(19) United States
(12) Patent Application Publication
(10) Pub. No.: US 2026/0341312 A1
(43) Pub. Date: Oct. 29, 2026

(54) PHASE CHANGE MEMORY DEVICE WITH ETCH-PROTECTION SIDEWALL SPACERS AND METHOD OF FORMING THE SAME

(71) Applicant: Taiwan Semiconductor Manufacturing Company Limited, Hsinchu (TW)

(72) Inventors: Jhih-Bin Chen, Hsinchu (TW); Yu-Wen Wang, Taichung City (TW)

(21) Appl. No.: 19/189,302

(22) Filed: Apr. 25, 2025

(51) Int. Cl. G11C 5/06; H10B 63/00; H10B 63/10; H10N 70/00; H10N 70/20; H10W 20/00

(52) U.S. Cl. CPC G11C 5/06; H10B 63/10; H10B 63/34; H10N 70/021; H10N 70/231; H10N 70/841; H10W 20/038

(57) ABSTRACT

A device structure may be provided by forming bottom electrodes within a dielectric material layer; depositing and patterning a layer stack including a bottom liner layer, a phase change material layer, and a top electrode material layer; depositing a spacer material layer on sidewalls of the patterned portions of the layer stack; and patterning the bottom liner layer such that patterned portions of the bottom liner layer includes a respective sidewall that is vertically coincident with an outer sidewall of a respective remaining portion of the spacer material layer.

### BACKGROUND

Phase change material (PCM) devices may be used for memory-based computing applications due to their scalability and non-volatility. These devices utilize the unique properties of phase change materials, which may switch between amorphous and crystalline states, to store information. However, during the manufacturing process of PCM devices, challenges may arise that may affect device performance and reliability. In particular, the PCM sidewall may be susceptible to damage or segregation during certain fabrication steps, such as the liner cutting process. This susceptibility to damage or segregation may impact the ability to control the phase transition between a crystalline state and an amorphous states in the PCM material, potentially affecting the device's functionality and performance characteristics.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. The dimensions of the various features may be arbitrarily increased or reduced for clarity of discussion.

FIG. 1 is a vertical cross-sectional view of a first embodiment structure after formation of field effect transistors, metal interconnect structures, and dielectric material layers according to a first embodiment of the present disclosure.

FIG. 2 is a vertical cross-sectional view of the first embodiment structure after formation of bottom electrodes according to the first embodiment of the present disclosure.

FIG. 3 is a vertical cross-sectional view of the first embodiment structure after formation of a continuous layer stack including a bottom liner layer, a phase change material layer comprising a phase change material, a top electrode material layer, and a hardmask material layer according to the first embodiment of the present disclosure.

FIG. 4 is a vertical cross-sectional view of the first embodiment structure after patterning the hardmask material layer, the top electrode material layer, and the phase change material layer into stacks of a hardmask plate, a top electrode, and a phase change material portion according to the first embodiment of the present disclosure.

FIG. 5 is a vertical cross-sectional view of the first embodiment structure after deposition of a spacer material layer according to the first embodiment of the present disclosure.

FIG. 6 is a vertical cross-sectional view of the first embodiment structure after a first anisotropic etch process that etches horizontally-extending portions of the spacer material layer according to the first embodiment of the present disclosure.

FIG. 7 is a vertical cross-sectional view of the first embodiment structure after a second anisotropic etch process that patterns the bottom liner layer into bottom liners according to the first embodiment of the present disclosure.

FIG. 8 is a vertical cross-sectional view of the first embodiment structure after formation of an encapsulation dielectric layer and additional metal interconnect structures according to the first embodiment of the present disclosure.

FIG. 9 is a vertical cross-sectional view of a second embodiment structure after patterning the hardmask material layer, the top electrode material layer, and the phase change material layer into in-process stacks of an in-process hardmask plate, an in-process top electrode, and an in-process phase change material portion according to a second embodiment of the present disclosure.

FIG. 10 is a vertical cross-sectional view of the second embodiment structure after deposition of a spacer material layer according to the second embodiment of the present disclosure.

FIG. 11 is a vertical cross-sectional view of the second embodiment structure after a first anisotropic etch process that etches horizontally-extending portions of the spacer material layer according to the second embodiment of the present disclosure.

FIG. 12 is a vertical cross-sectional view of the second embodiment structure after a second anisotropic etch process that patterns the bottom liner layer into in-process bottom liners according to the second embodiment of the present disclosure.

FIG. 13A-13C are sequential top-down views of a region of the second embodiment structure during patterning of the in-process stacks into stacks of a hardmask plate, a top electrode, and a phase change material portion and patterning of the in-process bottom liners into bottom liners according to the second embodiment of the present disclosure.

FIG. 14 is a vertical cross-sectional view of the second exemplary structure after formation of the stacks of a hardmask plate, a top electrode, and a phase change material portion according to the second embodiment of the present disclosure.

FIG. 15 is a vertical cross-sectional view of the second embodiment structure after formation of an encapsulation dielectric layer and additional metal interconnect structures according to the second embodiment of the present disclosure.

FIG. 16 is a vertical cross-sectional view of a third exemplary structure after patterning of the in-process stacks into stacks of a hardmask plate, a top electrode, and a phase change material portion according to a third embodiment of the present disclosure.

FIG. 17 is a vertical cross-sectional view of the third embodiment structure after deposition of an outer spacer material layer according to the third embodiment of the present disclosure.

FIG. 18 is a vertical cross-sectional view of the third embodiment structure after a first anisotropic etch process that etches horizontally-extending portions of the outer spacer material layer according to the third embodiment of the present disclosure.

FIG. 19 is a vertical cross-sectional view of the third embodiment structure after a second anisotropic etch process that patterns the in-process bottom liners into bottom liners according to the third embodiment of the present disclosure.

FIG. 20 is a vertical cross-sectional view of the third embodiment structure after formation of an encapsulation dielectric layer and additional metal interconnect structures according to the third embodiment of the present disclosure.

FIG. 21 is a first flowchart that illustrates general processing steps for manufacturing a device structure according to embodiments of the present disclosure.

FIG. 22 is a second flowchart that illustrates general processing steps for manufacturing a device structure according to embodiments of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. A first physical element is “embedded” with a second physical element in instances in which the entire volume of the first element is located within a hypothetical volume defined by a set of hypothetical surfaces having the least total surface area among all sets of hypothetical surfaces containing the entirety of the outer surfaces of the second element and topologically homeomorphic to a spherical surface. Such a set of hypothetical surfaces covers each opening, if present, in the outer surfaces with a minimum-area surface segment among all possible opening-free surface segments. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Unless explicitly stated otherwise, each material portion is presumed to have a homogeneous material composition throughout.

As used herein, removal of a first material is “selective to” a second material if the removal rate of the first material is greater than the removal rate of the second material at least by a factor of 3. Unless otherwise expressly indicated, removal of the first material selectively to the second material implies the possibility of the ratio of the removal rates equal to, or greater than, 3.0, and/or 10, and/or 100, and/or 1,000. As used herein, a first surface and a second surface are “vertically coincident” with each other if the second surface overlies or underlies the first surface and there exists a vertical plane or a substantially vertical plane that includes the first surface and the second surface. A vertical plane is a two-dimensional manifold containing a contiguous set of an uncountable infinity of vertical lines, and has a uniform one-dimensional horizontal cross-sectional shape that is invariant under translation along a vertical direction. The vertical plane may be a Euclidian plane if the uniform one-dimensional horizontal cross-sectional shape is a line, or may be a non-Euclidian plane if the uniform one-dimensional shape is not a line. A substantially vertical line is a straight line that deviates from a vertical direction by an angle less than 5 degrees. A substantially vertical plane is a two-dimensional manifold containing a contiguous set of an uncountable infinity of substantially vertical lines and/or vertical lines.

Phase change memory (PCM) devices may provide non-volatile storage and multi-level cell capabilities for memory-based computing applications. However, during manufacturing, the PCM sidewall may be susceptible to damage or segregation during the liner cutting process. Various embodiments disclosed herein provide a solution by forming a spacer before performing the liner cut. The various embodiments may protect the PCM sidewall and prevent damage or segregation during the liner cutting process. By depositing and etching the spacer material layer before patterning the bottom liner layer, the spacer may act as a protective barrier for the phase change material portion. This may help maintain the integrity of the PCM structure, potentially improving the control over phase changing between crystalline and amorphous states, which in turn may enhance the reliability and performance of the PCM device. The various embodiments of the present disclosure are now described with reference to accompanying drawings.

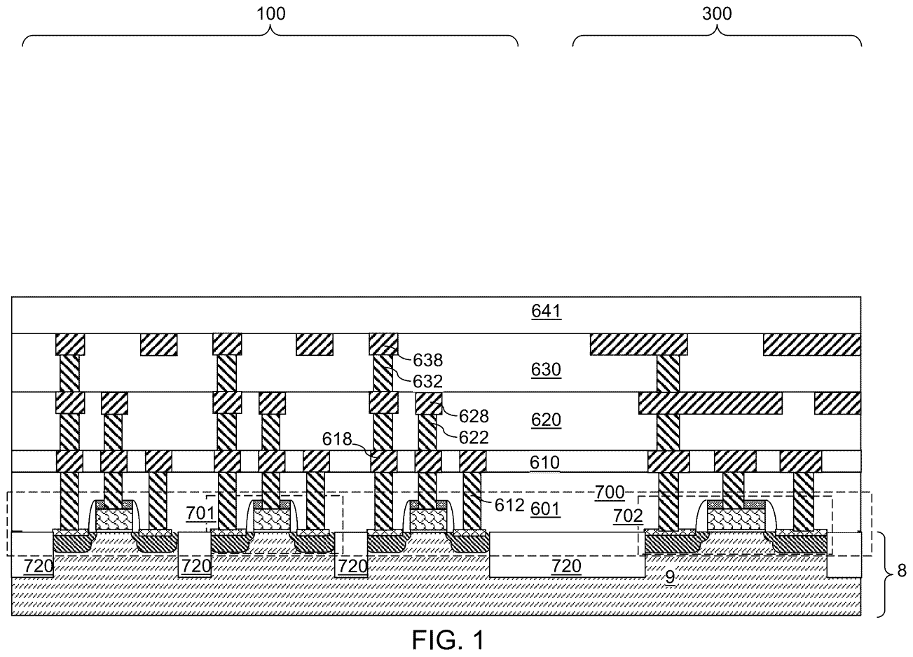

Referring to FIG. 1, a first embodiment structure according to the present disclosure is illustrated. The first embodiment structure includes a substrate 8, which may be a semiconductor substrate, such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720.

Semiconductor devices 700 may be formed on the semiconductor material layer 9. The semiconductor devices 700 may comprise complementary metal-oxide-semiconductor (CMOS) transistors and optionally additional semiconductor devices (such as resistors, diodes, capacitor structures, etc.). The semiconductor devices 700 may comprise programming transistors 701 that are formed in a memory array region 100, and peripheral transistors 702 that are formed in a peripheral region 300. Each field effect transistor (701, 702) may comprise a source region, a drain region, a channel region, a gate dielectric, and a gate electrode. In one embodiment, the channel region may comprise a portion of the semiconductor material layer 9, and may comprise a single crystalline semiconductor material. Each of the programming transistors 701 may be configured to provide a set of programming pulses for a respective phase change memory cell to be subsequently formed. The peripheral transistors 702 may be formed as components of a peripheral circuit that controls the operation of the programming transistors 701, and interfaces with an input/output (I/O) circuit (not illustrated).

In one embodiment, the substrate 8 may include a single crystalline silicon substrate, and the field effect transistors (701, 702) may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

Various metal interconnect structures embedded within dielectric material layers may be subsequently formed over the substrate 8 and the semiconductor devices. In an illustrative example, the dielectric material layers may include, for example, a first dielectric material layer 601 that may be a layer that surrounds the contact structure connected to the source and drains (sometimes referred to as a contact-level dielectric material layer 601), a first interconnect-level dielectric material layer 610, a second interconnect-level dielectric material layer 620, a third interconnect-level dielectric material layer 630, and a fourth interconnect-level dielectric material layer 640. The metal interconnect structures may include device contact via structures 612 formed in the first dielectric material layer 601 and contact a respective component of the semiconductor devices 700, first metal line structures 618 formed in the first interconnect-level dielectric material layer 610, first metal via structures 622 formed in a lower portion of the second interconnect-level dielectric material layer 620, second metal line structures 628 formed in an upper portion of the second interconnect-level dielectric material layer 620, second metal via structures 632 formed in a lower portion of the third interconnect-level dielectric material layer 630, and third metal line structures 638 formed in an upper portion of the third interconnect-level dielectric material layer 630. An additional dielectric material layer, which is herein referred to as a lower fourth interconnect-level dielectric material layer 641 may be formed over the third interconnect-level dielectric material layer 630.

Each of the dielectric material layers (601, 610, 620, 630, 641) may include a dielectric material such as undoped silicate glass, a doped silicate glass, organosilicate glass, amorphous fluorinated carbon, porous variants thereof, or combinations thereof. Each of the metal interconnect structures (612, 618, 622, 628, 632, 638) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. In one embodiment, the first metal via structures 622 and the second metal line structures 628 may be formed as integrated line and via structures by a dual damascene process. Generally, any contiguous set of a metal line structure (628, 638) and at least one underlying metal via structure (622, 632) may be formed as an integrated line and via structure.

Generally, semiconductor devices (such as field effect transistors (701, 702)) may be formed on a substrate 8, and metal interconnect structures (612, 618, 622, 628, 632, 638) and dielectric material layers (601, 610, 620, 630, 641) over the semiconductor devices. The metal interconnect structures (612, 618, 622, 628, 632, 638) may be formed in the dielectric material layers (601, 610, 620, 630, 641), and may be electrically connected to the semiconductor devices. In one embodiment, programming transistors 701 may be formed on a substrate 8. The metal interconnect structures (612, 618, 622, 628, 632, 638) may be configured to be electrically connected to heater elements of phase change memory cells to be subsequently formed. The metal interconnect structures (612, 618, 622, 628, 632, 638) are herein referred to as lower-level metal interconnect structures (612, 618, 622, 628, 632, 638), and the interconnect-level dielectric material layers (601, 610, 620, 630, 641) are herein referred to as lower-level dielectric material layers (601, 610, 620, 630, 641).

According to an aspect of the present disclosure, the programming transistors 701 may be configured to program a respective one of the phase change memory cells into at least two different resistive states, and preferably into at least three different resistive states, and more preferably into at least four different resistive states. The programming of each phase change memory cell into different resistive states may be effected by selecting a pulse pattern from a set of pre-programmed pulse patterns that each programming transistor 701 may apply.

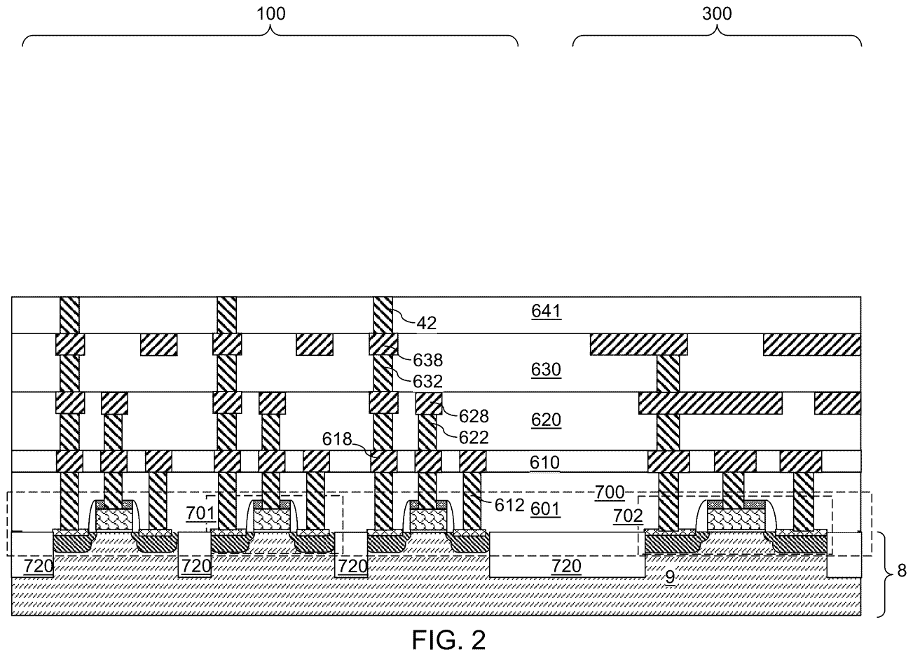

Referring to FIG. 2, cavities (such as via cavities) are formed through a topmost dielectric material layer (such as the lower fourth interconnect-level dielectric material layer 641) in the first embodiment structure. Each cavity may be formed over a respective one of the underlying metal interconnect structures (such as a subset of the third metal line structures 638) so that top surface segments of the underlying metal interconnect structures are physically exposed. The dielectric material layer, through which the cavities are formed, comprises a heat-resistant dielectric material such as undoped silicate glass or a doped silicate glass. The thickness of the dielectric material layer may be in a range from 20 nm to 100 nm, although lesser or greater thicknesses may also be used. In one embodiment, the cavities may be formed as via cavities having a respective lateral dimension (such as the diameter) in a range from 20 nm to 100 nm, although lesser or greater lateral dimensions may also be used.

At least one metallic material may be deposited in the cavities through the dielectric material layer. The at least one metallic material may comprise a combination of a metallic liner material and a metallic fill material. The metallic liner material may be a conductive metallic nitride material such as TiN, and the metallic fill material may comprise a high-conductivity metal such as tungsten. Excess portions of the at least one metallic material may be removed from above the horizontal plane including the top surface of the dielectric material layer (such as the lower fourth interconnect-level dielectric material layer 641) by performing a planarization process, which may comprise a recess etch process and/or a chemical mechanical polishing process. Each remaining portion of the at least one metallic material constitutes a bottom electrode 42. In one embodiment, the bottom electrodes 42 may be formed as metallic via structures each having a respective planar bottom surface, a respective planar top surface, and a respective set of at least one straight sidewall. Generally, bottom electrodes 42 are formed within a dielectric material layer (such as a lower fourth interconnect-level dielectric material layer 641).

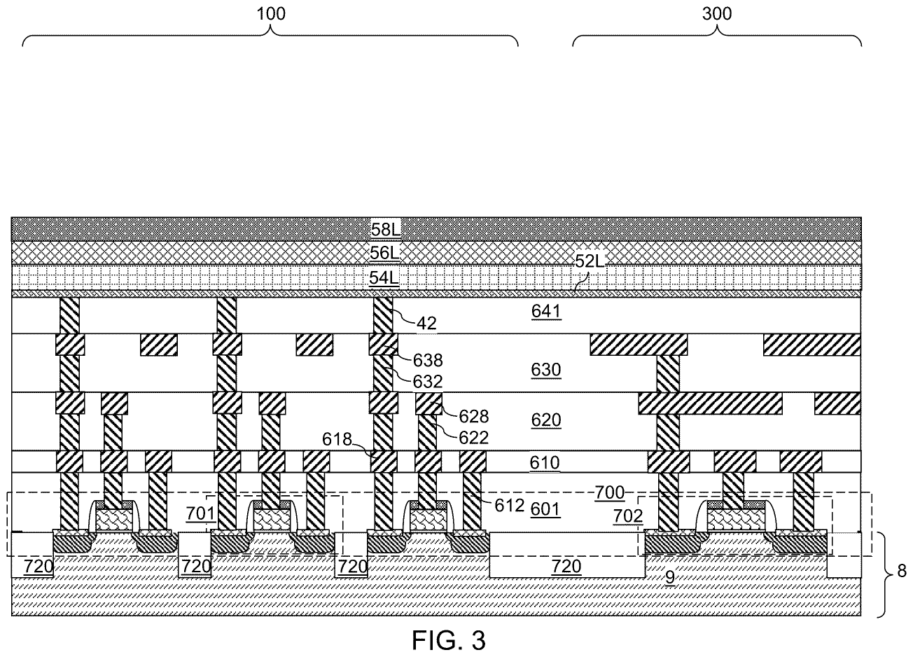

Referring to FIG. 3, a continuous layer stack (52L, 54L, 56L, 58L) including a bottom liner layer 52L, a phase change material layer 54L comprising a phase change material, a top electrode material layer 56L, and a hardmask material layer 58L may be deposited over the top surface of the dielectric material layer (such as the lower fourth interconnect-level dielectric material layer 641) that embeds the bottom electrodes 42.

The bottom liner layer 52L comprises a conductive material having a first electrical conductivity greater than 1.0×10⁵ S/m. In one embodiment, the bottom liner layer 52L comprises a first metallic nitride material, which may be a stoichiometric or near-stoichiometric metallic nitride material. For example, the bottom liner layer 52L may comprise TaN, TiN, WN, and/or MoN. In one embodiment, the electrical conductivity of the metallic material of the bottom liner layer 52L may be in a range from 1.0×10⁵ S/m to 1.0×10⁷ S/m. The thickness of the bottom liner layer 52L is selected such that patterned portions of the bottom liner layer 52L may provide electrical resistance during operation of phase memory cells to be subsequently formed. For example, the thickness of the bottom liner layer 52L may be in a range from 1 nm to 20 nm, such as from 2 nm to 4 nm, although lesser or greater thicknesses may also be used. The bottom liner layer 52L may be deposited by chemical vapor deposition or physical vapor deposition.

The phase change material layer 54L comprises, and/or consists essentially of, a phase change material. As used herein, a “phase change material” refers to a material having at least two different phases providing different resistivity. A phase change material (PCM) may be used to store information as a resistivity state of a material that may be in different resistivity states corresponding to different phases of the material. The different phases may include an amorphous state having high resistivity and a crystalline state having low resistivity (i.e., a lower resistivity than in the amorphous state). The transition between the amorphous state and the crystalline state may be induced by controlling the rate of cooling after application of an electrical pulse that renders the phase change material amorphous in a first part of a programming process. The second part of the programming process includes control of the cooling rate of the phase change material. In embodiments in which rapid quenching occurs, the phase change material may cool into an amorphous high resistivity state. In embodiments in which slow cooling occurs, the phase change material may cool into a crystalline low resistivity state.

Exemplary phase change materials include, but are not limited to, germanium antimony telluride (GST) compounds such as Ge₂Sb₂Te₅ or GeSb₂Te₄, germanium antimony compounds, indium germanium telluride compounds, aluminum selenium telluride compounds, indium selenium telluride compounds, and aluminum indium selenium telluride compounds. In one embodiment, the phase change material of the phase change material layer 54L may comprise a doped GST compound such as N-doped GST, Si-doped GST, C-doped GST, Ge-doped GST, Ru-doped GST, or Al-doped GST, or a doped GeTe compound such as N-doped GeTe, Si-doped GeTe, C-doped GeTe, or Ge-doped GeTe. The phase change material layer 54L may be deposited by physical vapor deposition. The thickness of the phase change material layer 54L may be in a range from 10 nm to 150 nm, such as from 20 nm to 100 nm, although lesser and greater thicknesses may also be used. In one embodiment, the phase change material of the phase change material layer may be selected such that the electrical conductivity of the amorphous phase of the phase change material is in a range from 1.0×10⁻⁶ S/m to 1.0×10⁻¹ S/m, while the electrical conductivity of the crystalline phase of the phase change material is in a range from 1.0×10¹ S/m to 1.0×10⁵ S/m.

The top electrode material layer 56L comprises a metallic material such as W, Ta, Ti, Mo, WN, TiN, WN, or MoN. The top electrode material layer 56L may have a thickness in a range from 10 nm to 100 nm, although lesser or greater thicknesses may also be used. The top electrode material layer 56L may be deposited by chemical vapor deposition or physical vapor deposition.

The hardmask material layer 58L comprises a dielectric hardmask material such as silicon nitride, silicon carbonitride, silicon oxide, a dielectric metal oxide, or a combination thereof. The thickness of the hardmask material layer 58L may be in a range from 5 nm to 100 nm, although lesser or greater thicknesses may also be used.

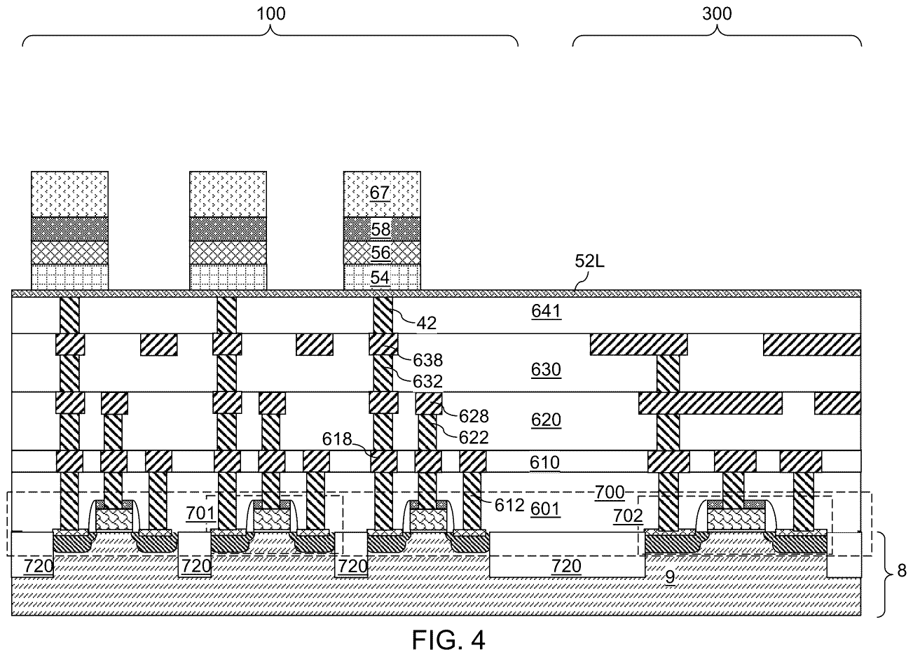

Referring to FIG. 4, the hardmask material layer 58L, the top electrode material layer 56L, and the phase change material layer 54L may be patterned into plate stacks (58, 56, 54). Specifically, a patterned etch mask layer 67 may be formed over the continuous layer stack (52L, 54L, 56L, 58L). For example, the patterned etch mask layer 67 may be formed by applying a photoresist layer over the continuous layer stack (52L, 54L, 56L, 58L), and lithographically patterning the photoresist layer into an array of discrete patterned photoresist material portions. In one embodiment, the patterned etch mask layer 67 may comprise a two-dimensional array, such as a two-dimensional rectangular periodic array, of patterned photoresist material portions that is located in the memory array region 100. In one embodiment, each patterned photoresist material portion may have a rectangular horizontal cross-sectional shape. The lateral dimensions, such as the length and the width, of each patterned photoresist material portion may be in a range from 20 nm to 100 nm, although lesser or greater lateral dimensions may also be used. In one embodiment, the lateral dimensions of each patterned photoresist material portion may be selected such that the area of a patterned photoresist material portion corresponds to the area of a single phase change memory material portion for a phase change memory cell.

An anisotropic etch process may be performed to etch portions of the hardmask material layer 58L, the top electrode material layer 56L, and the phase change material layer 54L that are not masked by the patterned etch mask layer 67. The anisotropic etch process has an etch chemistry that etches the materials of the hardmask material layer 58L, the top electrode material layer 56L, and the phase change material layer 54L selectively to the material of the bottom liner layer 52L. The anisotropic etch process may include multiple steps to sequentially etch the hardmask material layer 58L, the top electrode material layer 56L, and the phase change material layer 54L.

For example, the anisotropic etch process may comprise a first anisotropic etch step that etches unmasked portions of the hardmask material layer 58L, a second anisotropic etch step that etches unmasked portions of the top electrode material layer 56L, and a third anisotropic etch step that etches unmasked portions of the phase change material layer 54L. The etch chemistry for the first anisotropic etch step may include fluorine-based gases such as CF₄, CHF₃, and/or SF₆, which are effective in etching dielectric materials like silicon nitride, silicon carbonitride, silicon oxide, or dielectric metal oxides. The top electrode material layer 56L may comprise a metallic material such as W, Ta, Ti, Mo, WN, TiN, and/or MoN, the etch chemistry of the second anisotropic etch step may include chlorine-based gases such as Cl₂ or BCl₃, and may optionally include Ar or N₂.

The third anisotropic etch step etches unmasked portions of the phase change material layer 54L. In instances in which the phase change material layer 54L comprises a GST compound or a doped variant thereof, the etch chemistry of the third anisotropic etch step may include halogen-based gases. According to an aspect of the present disclosure, the etch chemistry for the third anisotropic etch step may be selective to the material of the bottom liner layer 52L. The bottom liner layer 52L is not etched during the third anisotropic etch step due to the selectivity of the etch chemistry of the third anisotropic etch process with respect to the material of the bottom liner layer 52L. Generally, metallic materials may be anisotropically etched using a halogen-based etch chemistry. However, the sidewalls of the patterned portions of the phase change material layer 54L are susceptible to damage from a halogen-based gas etch chemistry. By not patterning the bottom liner layer 52L while the sidewalls of the patterned portions of the phase change material layer 54L are physically exposed, chemical and structural damages to the material of the patterned portions of the phase change material layer 54L are avoided. Lack of damages to the material of the patterned portions of the phase change material layer 54L allows phase change memory cells to be subsequently formed to provide consistent and reliable switching characteristics between a low resistance state and a high resistance state.

Each patterned portion of the hardmask material layer 58L comprises a hardmask plate 58. Each patterned portion of the top electrode material layer 56L comprises a top electrode 56. Each patterned portion of the phase change material layer 54L comprises a phase change material portion 54. Thus, the combination of the hardmask material layer 58L, the top electrode material layer 56L, and the phase change material layer 54L is patterned into plate stacks (58, 56, 54) each including a phase change material portion 54, a top electrode 56, and a hardmask plate 58. Within each plate stack (58, 56, 54), the sidewalls of the phase change material portion 54, the top electrode 56, and the hardmask plate 58 are vertically coincident to one another. The patterned etch mask layer 67 may be subsequently removed, for example, by ashing or dissolution in a solvent.

In summary, plate stacks (58, 56, 54) containing a respective patterned portion of the top electrode material layer 56L and a respective patterned portion of the phase change material layer 54L may be formed by patterning the top electrode material layer 56L and the phase change material layer 54L. The hardmask material layer 58L, the top electrode material layer 56L, and the phase change material layer 54L are patterned into the plate stacks (58′, 56′, 54′) by performing an anisotropic etch process that etches materials of the top electrode material layer 56L and the phase change material layer 54L selectively to the material of the bottom liner layer 52L. In one embodiment, the bottom liner layer 52L covers, and contacts, an entire top surface of a dielectric material layer (such as a lower fourth interconnect-level dielectric material layer 641) after patterning the hardmask material layer 58L, the top electrode material layer 56L, and the phase change material layer 54L into the plate stacks (58, 56, 54).

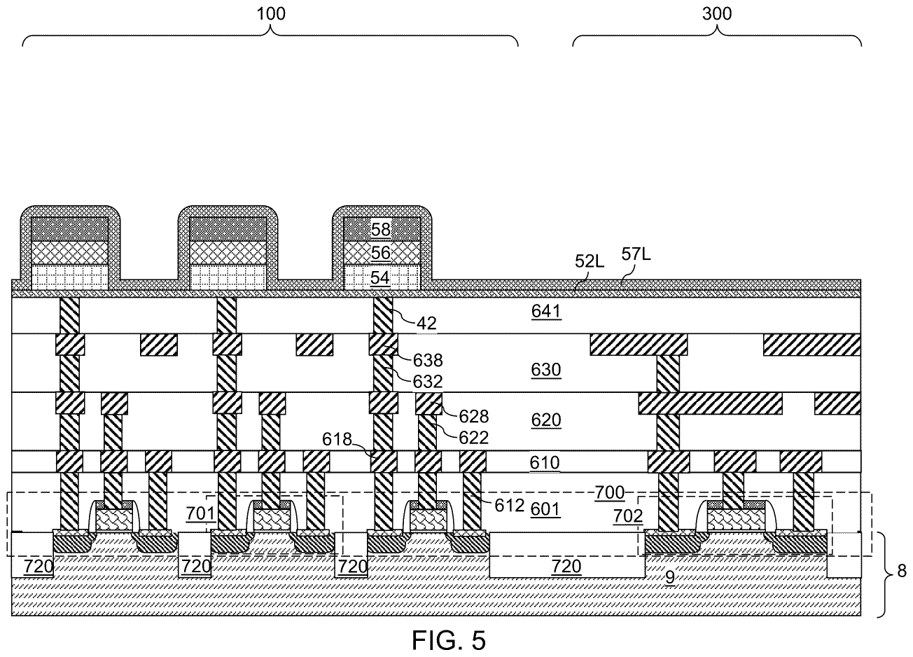

Referring to FIG. 5, a spacer material layer 57L may be deposited on the physically exposed surfaces of the plate stacks (58, 56, 54) and on the physically exposed segments of the top surface of the bottom liner layer 52L. The spacer material layer 57L comprises a material having a lower electrical conductivity than the material of the bottom liner layer 52L. In one embodiment, the spacer material layer 57L comprise a material having an electrical conductivity that is less than 1/100 of the electrical conductivity of the material of the bottom liner layer 52L. In one embodiment, the spacer material layer 57L comprises a material having a second electrical conductivity in a range from 1.0×10⁻¹⁵ S/m to 1.0×10³ S/m. In one embodiment, the spacer material layer 57L comprises an insulator material having an electrical conductivity less than 1.0×10⁻⁵ S/m. In another embodiment, the spacer material layer 57L comprises a semiconducting material having an electrical conductivity in a range from 1.0×10⁻⁵ S/m to 1.0×10⁵ S/m. The thickness of the spacer material layer 57L may be in a range from 1 nm to 20 nm, such as from 2 nm to 4 nm, although lesser or greater thicknesses may also be used.

The spacer material layer 57L is deposited directly on all sidewalls of the plate stacks (58, 56, 54) and a top surface of a remaining portion of the bottom liner layer 52L (which may be the entirety of the bottom liner layer 52L) after patterning the hardmask material layer 58L, the top electrode material layer 56L, and the phase change material layer 54L into the plate stacks (58, 56, 54). In other words, all sidewalls of the plate stacks (58, 56, 54) are contacted by the spacer material layer 57L upon deposition of the spacer material layer 57L. Thus, vertically-extending portions of the spacer material layer 57L contact all sidewalls of a respective one of the top electrodes 56 and all sidewalls of a respective one of the phase change material portions 54.

In one embodiment, the spacer material layer 57L may comprise a metallic nitride material layer that is deposited by a conformal deposition process such as a chemical vapor deposition process. In one embodiment, the spacer material layer 57L may comprise a second metallic nitride material, which may comprise, and/or may consist essentially of, TiN, TaN, WN, and/or MoN. In this embodiment, the electrical conductivity of the second metallic nitride material may be reduced by incorporating carbon atoms or nitrogen atoms into the metallic nitride material layer by in-situ doping or ex-situ doping of carbon atoms or nitrogen atoms, i.e., incorporation of the carbon atoms or the nitrogen atoms during deposition of the spacer material layer 57L or after deposition of the spacer material layer 57L. For example, the carbon atoms or the nitrogen atoms may be provided by a reactive carbon-containing gas (such as acetylene or ethylene) or a reactive nitrogen-containing gas (such as ammonia) during a chemical vapor deposition that deposits the spacer material layer 57L. Alternatively, the spacer material layer 57L may be exposed to an ambient containing reactive carbon-containing species or reactive nitrogen-containing species at an elevated temperature after the deposition process that deposits the spacer material layer 57L. Yet alternatively, an ion implantation process or a plasma doping process may be performed after the deposition process that deposits the spacer material layer 57L.

The carbon atoms or the nitrogen atoms are incorporated into the second metallic nitride material of the spacer material layer 57L at an atomic concentration such that the electrical conductivity of the doped metallic nitride material of the spacer material layer 57L after incorporation of the carbon atoms or the nitrogen atoms is less than ⅓ of the electrical conductivity of the second metallic nitride material prior to the incorporation of the carbon atoms or the nitrogen atoms. In an illustrative example, the electrical conductivity of the spacer material layer 57L after incorporation of the carbon atoms or the nitrogen atoms may be in a range from 1.0×10¹ S/cm to 1.0×10⁵ S/cm.

Generally, the ratio of the metal atoms to nitrogen atoms in a stoichiometric metallic compound MN, in which M is Ta, Ti, Mo, or W, is 1:1. In embodiments in which nitrogen doping is used, upon doping of a stoichiometric metallic compound with nitrogen atoms to form the spacer material layer 57L of the present disclosure, the ratio of the metal atoms to nitrogen atoms in the spacer material layer 57L may be in a range from 1:1.02 to 1:1.05. In embodiments in which carbon doping is used, upon doping of a stoichiometric metallic compound with carbon atoms to form the spacer material layer 57L of the present disclosure, the ratio of the metal atoms to nitrogen atoms to carbon atoms in the spacer material layer 57L may be in a range from 1:1:0.02 to 1:1:0.05. Generally, the atomic concentration of the extra nitrogen atoms in a nitrogen-doped metallic nitride material may be in a range from 0.02 times the atomic concentration of the metal atoms to 0.05 times the atomic concentration of the metal atoms. Likewise, the atomic concentration of the carbon atoms in a carbon-doped metallic nitride material may be in a range from 0.02 times the atomic concentration of the metal atoms to 0.05 times the atomic concentration of the metal atoms.

In one embodiment, the second metallic nitride material of the spacer material layer 57L after the doping process may have an electrical conductivity that is less than 1/100 of the electrical conductivity of the first metallic nitride material of the bottom liners 52. In one embodiment, the first metallic nitride material of the bottom liner layer 52L and the second metallic nitride material (which is a doped metallic nitride material) of the spacer material layer 57L are selected such that the resistance of a bottom liner 52 and the resistance of a sidewall spacer to be patterned from the spacer material layer 57L dominate the resistance of a phase memory material cell in a high resistance state. In this embodiment, the resistance of the amorphous volume of a phase change material portion does not determine the resistance of high resistance states of a phase change memory cell. Thus, the phase change memory cell may operate without significant degradation caused by any resistance drift of a phase change material.

Alternatively, the spacer material layer 57L may consist of at least one insulating material such as silicon oxide, silicon nitride, and/or a dielectric metal oxide. In this embodiment, the resistance of a bottom liner 52 and the resistance of a phase change material portion 54 in an amorphous phase may dominate the resistance of states of phase memory material cells in a high resistance state.

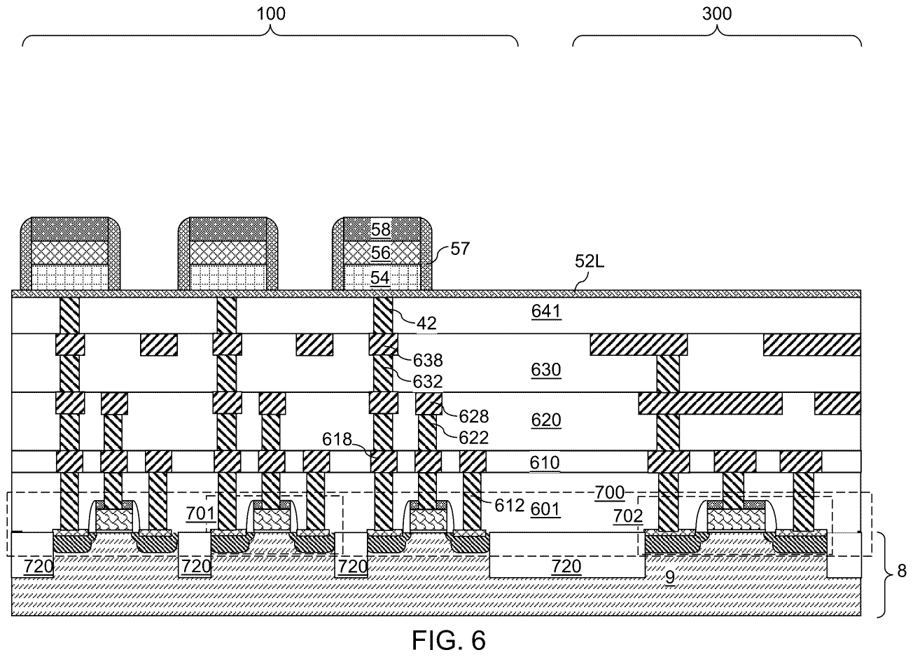

Referring to FIG. 6, a first anisotropic etch process may be performed to remove horizontally-extending portions of the spacer material layer 57L. The first anisotropic etch process is also referred to as a spacer etch process. The first anisotropic etch process anisotropically etches the material of the spacer material layer 57L, and removes horizontally-extending portions of the spacer material layer 57L. The etch chemistry of the first anisotropic etch process may be selective to the material of the bottom liner layer 52L. Each remaining vertically-extending portion of the spacer material layer 57L constitutes a sidewall spacer 57 that laterally surrounds a respective plate stack (58, 56, 54). Each sidewall spacer 57 contacts all sidewalls of the phase change material portion 54, the top electrode 56, and the hardmask plate 58 of a respective plate stack (58, 56, 54). Generally, a sidewall spacer 57 may be formed around each plate stack (58, 56, 54) by conformally depositing and anisotropically etching a layer of the sidewall spacer material.

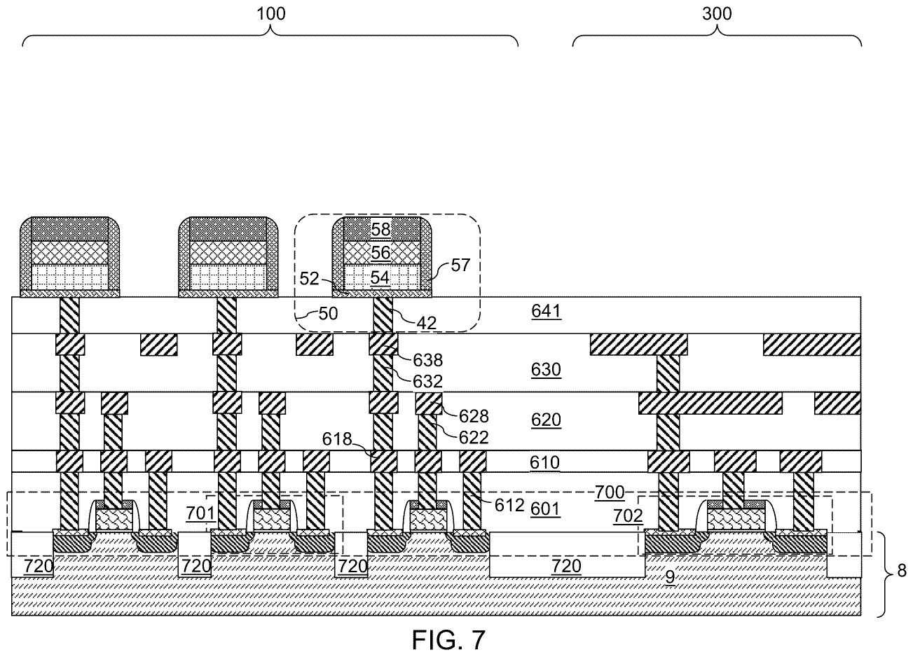

Referring to FIG. 7, a second anisotropic etch process may be performed to etch unmasked portions of the bottom liner layer 52L. The second anisotropic etch process is also referred to as a bottom-liner etch process. The second anisotropic etch process anisotropically etches unmasked portions of the material of the bottom liner layer 52L that are not covered by the combination of the plate stacks (58, 56, 54) and the sidewall spacers 57 (which are vertically-extending remaining portions of the spacer material layer 57L). Each patterned remaining portions of the bottom liner layer 52L constitutes a bottom liner 52. Each bottom liner 52 comprises a respective sidewall that is vertically coincident with an outer sidewall of a respective overlying sidewall spacer 57 (which is a remaining portion of the spacer material layer 57L). Thus, the second anisotropic etch process patterns the bottom liner layer 52L into bottom liners 52. Each of the bottom liners 52 may have a set of sidewalls that are vertically coincident with outer sidewalls of a respective overlying sidewall spacer 57. In one embodiment, each sidewall of the bottom liners 52 may be vertically coincident with an outer sidewall of a respective overlying sidewall spacer 57.

Each contiguous combination of a bottom electrode 42, a bottom liner 52, a phase change material portion 54, a top electrode 56, a hardmask plate 58, and a sidewall spacer 57 constitutes a phase change memory cell 50. A two-dimensional array of phase change memory cells 50 may be formed in the memory array region 100. For each phase change memory cell 50, a peripheral segment of the top surface of the bottom liner 52 has a frame shape having an inner periphery and an outer periphery that is laterally offset outward relative to the inner periphery by a uniform lateral offset distance (which equals a lateral thickness of a sidewall spacer 57). In one embodiment, a frame-shaped bottom surface of the sidewall spacer 57 contacts an entirety of the peripheral segment of the top surface of the bottom liner 52.

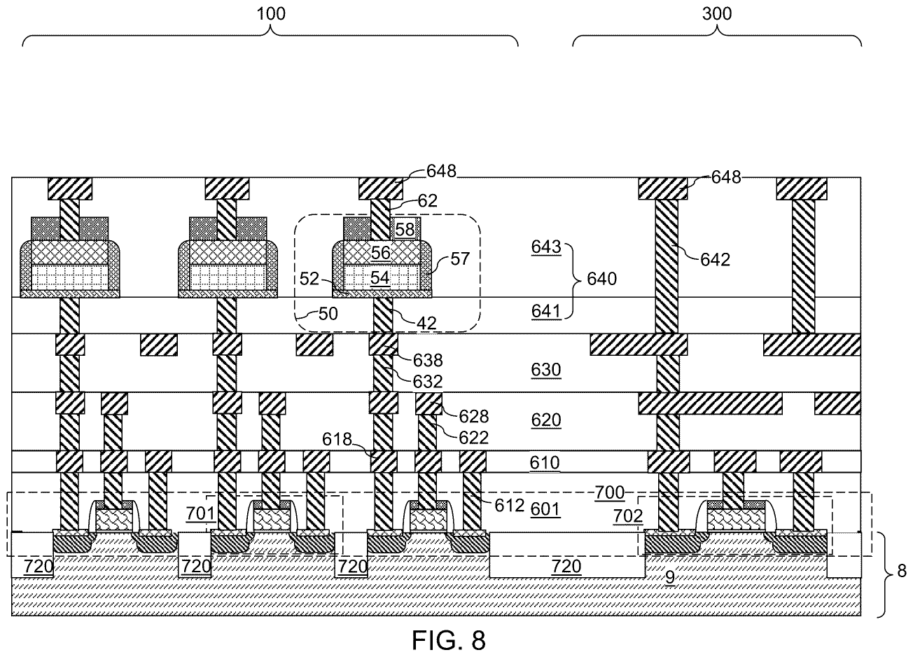

Referring to FIG. 8, an encapsulation dielectric layer 643 and additional metal interconnect structures (62, 642, 648) may be formed over the phase change memory cells 50. The encapsulation dielectric layer 643 comprises at least one interlayer dielectric material such as silicon oxide, silicon nitride, and/or silicon carbide nitride. The additional metal interconnect structures (62, 642, 648) may comprise top-contact via structures 62 contacting a top surface of a respective one of the top electrodes 56, peripheral via structures 642 that are formed on a respective one of the lower-level metal interconnect structures (612, 618, 622, 628, 632, 638) (such as a respective one of the third metal line structures 638), and fourth metal line structures 648 that are formed on the top-contact via structures 62 and the peripheral via structures 642. Top surfaces of the fourth metal line structures 648 may be coplanar with the horizontal top surface of the encapsulation dielectric layer 643.

The encapsulation dielectric layer 643 constitutes an upper fourth interconnect-level dielectric material layer. The combination of the lower fourth interconnect-level dielectric material layer 641 and the encapsulation dielectric layer 643 constitutes a fourth interconnect-level dielectric material layer 640. Additional dielectric material layers (not shown) and additional metal interconnect structures may be formed to provide electrical connections between the top electrodes 56 of the phase change memory cells 50 and the various semiconductor devices 700 that underlie the dielectric material layers (601, 610, 620, 630, 640).

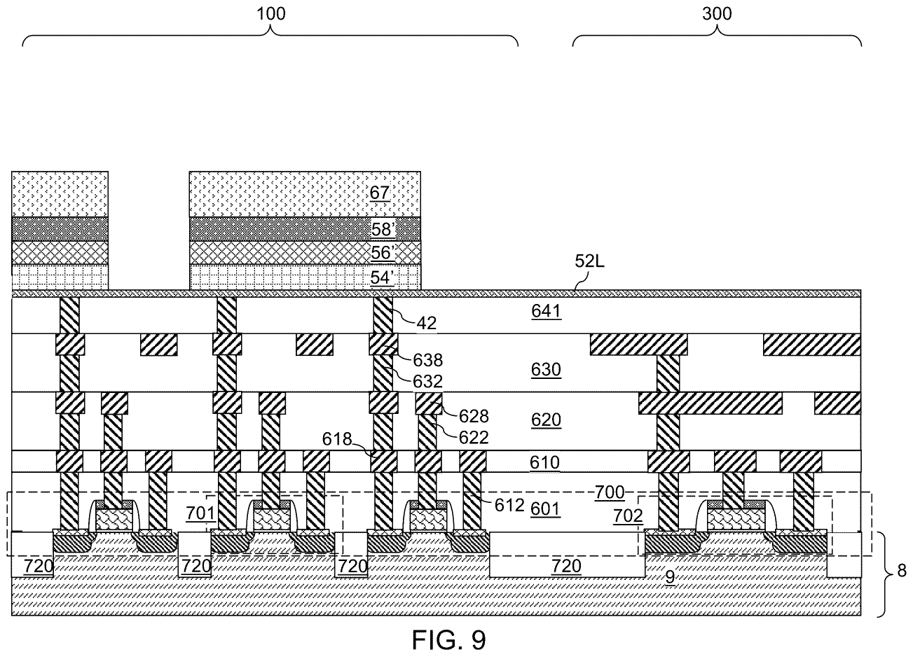

Referring to FIG. 9, a second embodiment structure may be derived from the first embodiment structure illustrated in FIG. 3 by patterning the stack of the hardmask material layer 58L, the top electrode material layer 56L, and the phase change material layer 54L into plate stacks (58′, 56′, 54′). Specifically, a patterned etch mask layer 67 may be formed over the continuous layer stack (52L, 54L, 56L, 58L). For example, the patterned etch mask layer 67 may be formed by applying a photoresist layer over the continuous layer stack (52L, 54L, 56L, 58L), and lithographically patterning the photoresist layer into an array of discrete patterned photoresist material portions. In one embodiment, the patterned etch mask layer 67 may comprise a two-dimensional array, such as a two-dimensional rectangular periodic array, of patterned photoresist material portions that is located in the memory array region 100. In one embodiment, each patterned photoresist material portion may have a rectangular horizontal cross-sectional shape.

According to an aspect of the present disclosure, at least one of the lateral dimensions, such as the length and the width, of each patterned photoresist material portion may be greater than the lateral dimensions of phase change material portions to be used in phase change memory cells at least by a factor of 2. In one embodiment, at least one of the lateral dimensions of each patterned photoresist material portion may be greater than 40 nm, and may be in a range from 240 nm to 1 mm, although greater lateral dimensions may also be used. In one embodiment, the lateral dimensions of each patterned photoresist material portion may be selected such that the area of a patterned photoresist material portion contains areas for forming at least two phase change memory material portions for at least two phase change memory cells.

An anisotropic etch process may be performed to etch portions of the hardmask material layer 58L, the top electrode material layer 56L, and the phase change material layer 54L that are not masked by the patterned etch mask layer 67. The anisotropic etch process has an etch chemistry that etches the materials of the hardmask material layer 58L, the top electrode material layer 56L, and the phase change material layer 54L selectively to the material of the bottom liner layer 52L. The anisotropic etch process may include multiple steps to sequentially etch the hardmask material layer 58L, the top electrode material layer 56L, and the phase change material layer 54L.

For example, the anisotropic etch process may comprise a first anisotropic etch step that etches unmasked portions of the hardmask material layer 58L, a second anisotropic etch step that etches unmasked portions of the top electrode material layer 56L, and a third anisotropic etch step that etches unmasked portions of the phase change material layer 54L. The etch chemistry of each anisotropic etch step may be the same as described above. As discussed above, the etch chemistry for the third anisotropic etch step may be selective to the material of the bottom liner layer 52L. The bottom liner layer 52L is not etched during the third anisotropic etch step due to the selectivity of the etch chemistry of the third anisotropic etch process with respect to the material of the bottom liner layer 52L. Generally, metallic materials may be anisotropically etched using a halogen-based etch chemistry. However, the sidewalls of the patterned portions of the phase change material layer 54L are susceptible to damage from a halogen-based gas etch chemistry. By not patterning the bottom liner layer 52L while the sidewalls of the patterned portions of the phase change material layer 54L are physically exposed, chemical and structural damages to the material of the patterned portions of the phase change material layer 54L are avoided. Lack of damage to the material of the patterned portions of the phase change material layer 54L allows phase change memory cells to be subsequently formed to provide consistent and reliable switching characteristics between a low resistance state and a high resistance state.

Each patterned portion of the hardmask material layer 58L comprises an in-process hardmask plate 58′. Each patterned portion of the top electrode material layer 56L comprises an in-process top electrode 56′. Each patterned portion of the phase change material layer 54L comprises an in-process phase change material portion 54′. As used herein, an “in-process” element refers to an element that is subsequently modified structurally or compositionally. Thus, the combination of the hardmask material layer 58L, the top electrode material layer 56L, and the phase change material layer 54L is patterned into plate stacks (58′, 56′, 54′) each including an in-process phase change material portion 54′, an in-process top electrode 56′, and an in-process hardmask plate 58′. Within each plate stack (58′, 56′, 54′), the sidewalls of the in-process phase change material portion 54′, the in-process top electrode 56′, and the in-process hardmask plate 58′ are vertically coincident to one another. The patterned etch mask layer 67 may be subsequently removed, for example, by ashing or dissolution in a solvent.

In summary, plate stacks (58′, 56′, 54′) containing a respective patterned portion of the top electrode material layer 56L and a respective patterned portion of the phase change material layer 54L may be formed by patterning the top electrode material layer 56L and the phase change material layer 54L. The hardmask material layer 58L, the top electrode material layer 56L, and the phase change material layer 54L are patterned into the plate stacks (58′, 56′, 54′) by performing an anisotropic etch process that etches materials of the top electrode material layer 56L and the phase change material layer 54L selectively to the material of the bottom liner layer 52L. In one embodiment, the bottom liner layer 52L covers, and contacts, an entire top surface of a dielectric material layer (such as a lower fourth interconnect-level dielectric material layer 641) after patterning the hardmask material layer 58L, the top electrode material layer 56L, and the phase change material layer 54L into the plate stacks (58′, 56′, 54′). In one embodiment, the hardmask material layer 58L, the top electrode material layer 56L, and the phase change material layer 54L may be patterned into in-process stacks (58′, 56′, 54′) of an in-process hardmask plate 58′, an in-process top electrode 56′, and an in-process phase change material portion 54'.

In the second embodiment structure, each plate stack (58′, 56′, 54′) comprises a respective vertical stack of a respective patterned portion of the hardmask material layer 58L, a respective patterned portion of the top electrode material layer 56L, and a respective patterned portion of the phase change material layer 54L. The respective patterned portion of the hardmask material layer 58L comprises a respective in-process hardmask plate 58′. The respective patterned portion of the top electrode material layer 56L comprises a respective in-process top electrode 56′. The respective patterned portion of the phase change material layer 54L comprises a respective in-process phase change material portion 54′.

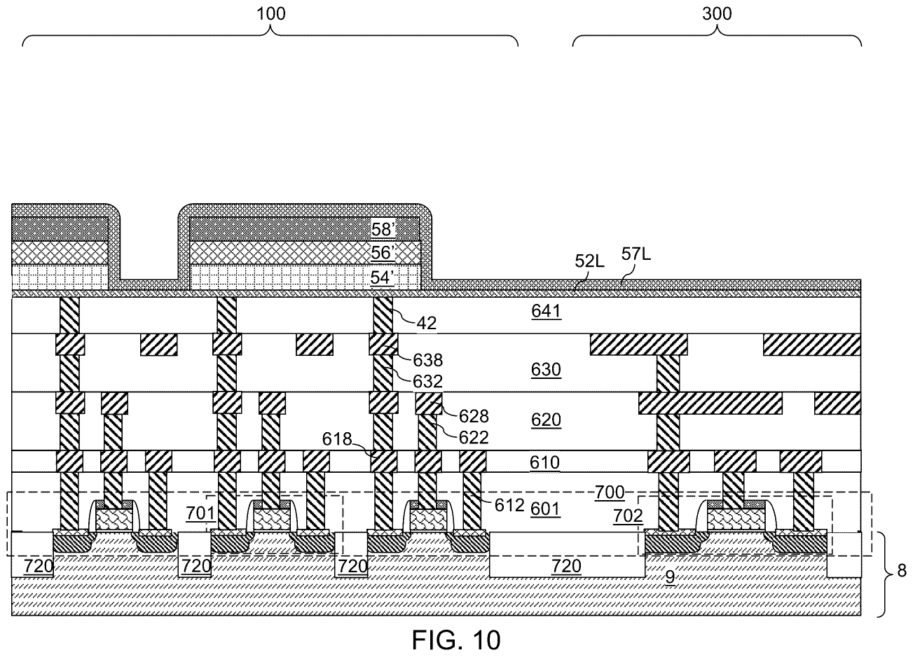

Referring to FIG. 10, the processing steps described with reference to FIG. 5 may be performed to form a spacer material layer 57L on sidewalls of the plate stacks (58′, 56′, 54′). The material composition and the thickness of the spacer material layer 57L may be the same as described above. The spacer material layer 57L is deposited directly on a top surface of a remaining portion of the bottom liner layer 52L after patterning the top electrode material layer 56L and the phase change material layer 54L into the plate stacks (58′, 56′, 54′). In one embodiment, all sidewalls of the plate stacks (58′, 56′, 54′) are contacted by the spacer material layer 57L upon deposition of the spacer material layer 57L.

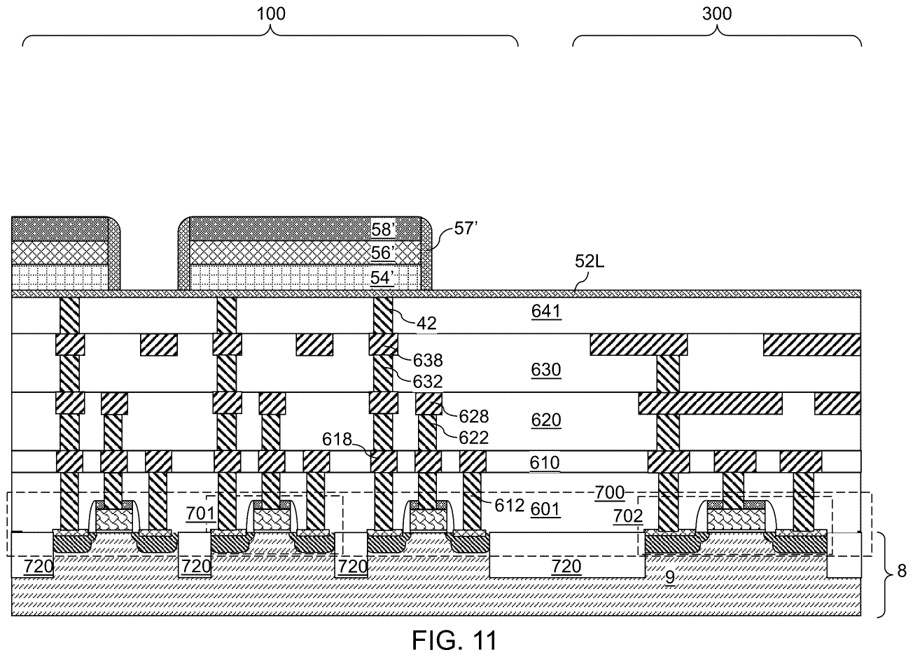

Referring to FIG. 11, the processing steps described with reference to FIG. 6 may be performed to remove horizontally-extending portions of the spacer material layer 57L. For example, a first anisotropic etch process, i.e., a spacer etch process, may be performed to anisotropically etch the material of the spacer material layer 57L. The etch chemistry of the first anisotropic etch process may be selective to the material of the bottom liner layer 52L. Each remaining vertically-extending portion of the spacer material layer 57L constitutes an in-process sidewall spacer 57′ that laterally surrounds a respective plate stack (58′, 56′, 54′). Each sidewall spacer 57 contacts all sidewalls of the in-process phase change material portion 54′, the in-process top electrode 56′, and the in-process hardmask plate 58′ of a respective plate stack (58′, 56′, 54′). Generally, an in-process sidewall spacer 57′ may be formed around each plate stack (58′, 56′, 54′) by conformally depositing and anisotropically etching a layer of the sidewall spacer material.

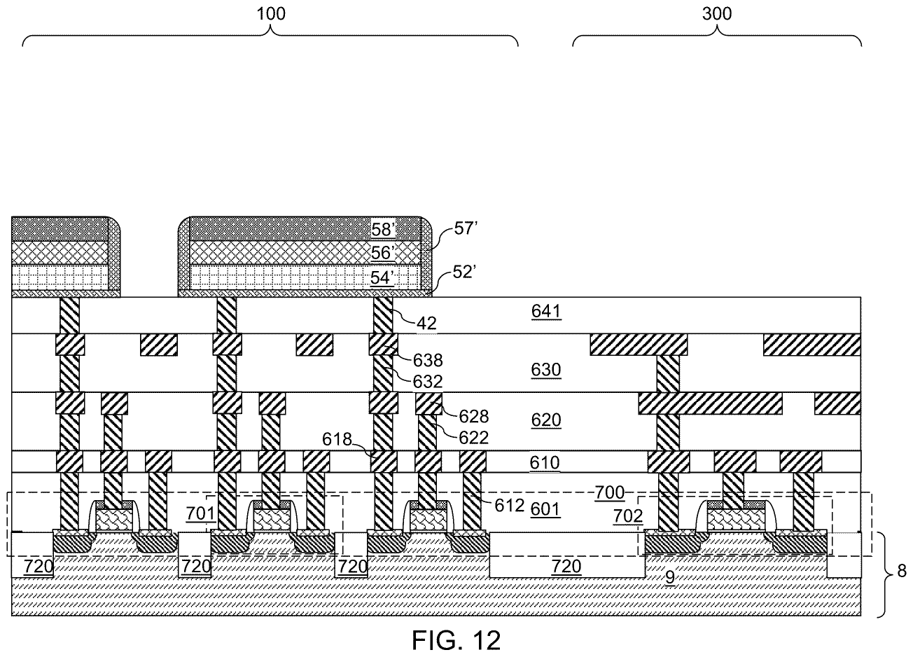

Referring to FIG. 12, a second anisotropic etch process may be performed to etch unmasked portions of the bottom liner layer 52L. The second anisotropic etch process is also referred to as a first bottom-liner etch process. The second anisotropic etch process anisotropically etches unmasked portions of the material of the bottom liner layer 52L that are not covered by the combination of the plate stacks (58′, 56′, 54′) and the in-process sidewall spacers 57′ (which are vertically-extending remaining portions of the spacer material layer 57L). Each patterned remaining portions of the bottom liner layer 52L constitutes an in-process bottom liner 52′. Each in-process bottom liner 52′ comprises a respective sidewall that is vertically coincident with an outer sidewall of a respective overlying in-process sidewall spacer 57′ (which is a remaining portion of the spacer material layer 57L). Thus, the second anisotropic etch process patterns the bottom liner layer 52L into in-process bottom liners 52′. Each of the in-process bottom liners 52′ may have a set of sidewalls that are vertically coincident with outer sidewalls of a respective overlying in-process sidewall spacer 57′. In one embodiment, each sidewall of the in-process bottom liners 52′ may be vertically coincident with an outer sidewall of a respective overlying in-process sidewall spacer 57′.

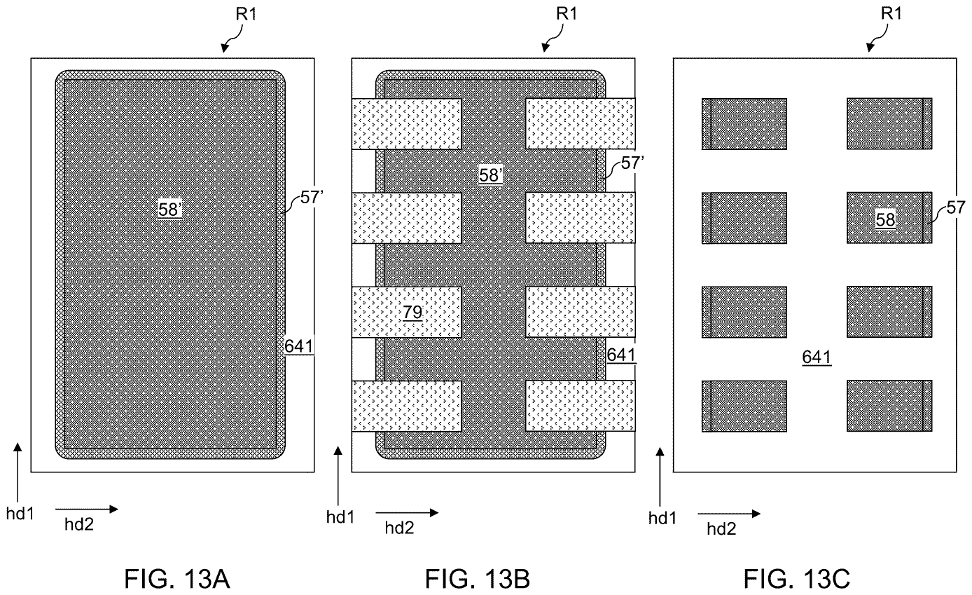

FIG. 13A-13C are sequential top-down views of a region of the second embodiment structure during patterning of the plate stacks (58′, 56′, 54′) into stacks of a hardmask plate 58, a top electrode 56, and a phase change material portion 54 and patterning of the in-process bottom liners 52′ into bottom liners 52 according to the second embodiment of the present disclosure.

Referring to FIG. 13A, a region of the second embodiment structure including a plate stack (58′, 56′, 54′) and an in-process sidewall spacer 57′ is illustrated at the processing step of FIG. 12. The in-process layer stack (58′, 56′, 54′) may comprise first sidewalls that are parallel to a first horizontal direction hd1 and second sidewalls that are parallel to a second horizontal direction hd2. The second horizontal direction hd2 may be perpendicular to the first horizontal direction hd1.

Referring to FIG. 13B, the region of the second embodiment structure is illustrated after formation of a second patterned etch mask layer 79, which may be a patterned photoresist layer. The second etch mask layer 79 has a pattern that is different from the pattern of the etch mask layer 67 used at the processing steps of FIG. 9, which may be referred to as a first etch mask layer 67. The illustrated portion of the second patterned etch mask layer 79 may comprise a two-dimensional array, such as a 2×N array, of patterned discrete etch mask material portions (such as patterned photoresist material portions) that cover 2N segments of the first sidewalls of the in-process layer stack (58′, 56′, 54′). In the illustrated example, the integer N is 4. Generally, the integer N may be any positive integer. As discussed above, the in-process layer stack (58′, 56′, 54′) comprises first sidewalls that laterally extend along the first horizontal direction hd1 and second sidewalls that laterally extend along the second horizontal direction hd2. The masking material portions of the second patterned etch mask layer 79 laterally extend along the second horizontal direction hd2, and may be laterally spaced apart from one another along the first horizontal direction hd1.

Referring to FIG. 13C, an anisotropic etch process may be performed to etch unmasked portions of the in-process hardmask plates 58′, the in-process top electrodes 56′, the in-process phase change material portions 54′, the in-process sidewall spacers 57′, and the in-process bottom liners 52′. The anisotropic etch process etches unmasked regions of the combination of the plate stacks (58′, 56′, 54′), the in-process sidewall spacers 57′ (which are remaining portion of the spacer material layer 57L after the processing steps of FIG. 12), and the in-process bottom liners 52′ (which are the patterned remaining portions of the bottom liner layer 52L after the processing steps of FIG. 12) that are not covered by the second patterned etch mask layer 79 (which may be a patterned photoresist layer). Each contiguous set of patterned portions of a plate stack (58′, 56′, 54′) comprises a layer stack (58, 56, 54) including a respective hardmask plate 58, a respective top electrode 56, and a respective phase change material portion 54.

Thus, the anisotropic etch process further patterns the remaining patterned portions of the hardmask material layer 58L, the remaining patterned portions of the top electrode material layer 56L, the remaining patterned portions of the phase change material layer 54L, and the remaining portions of the spacer material layer 57L that remain after the processing steps of FIG. 12 (i.e., the first bottom-liner etch process). Remaining portions of the hardmask material layer 58L after the anisotropic etch process comprises hardmask plates 58. Remaining portions of the top electrode material layer 56L after the anisotropic etch process comprises top electrodes 56. Remaining portions of the phase change material layer 54L after the anisotropic etch process comprises phase change material portions 54.

The anisotropic etch process etches unmasked portions of the in-process bottom liners 52′, which are patterned portions of the bottom liner layer 52L after the processing steps of FIG. 12. Remaining portions of the bottom liner layer 52L after the second anisotropic etch process comprises bottom liners 52. The step of the second anisotropic etch process that etches the material of the bottom liner layer 52L is herein referred to as a second bottom-liner etch process. Each of the bottom liners 52 is formed with at least one first sidewall that is vertically coincident with an outer sidewall of a respective overlying one of the sidewall spacers 57. Further, each of the bottom liners 52 is formed with at least one second sidewall that is vertically coincident with a sidewall of a respective overlying one of the phase change material portions 54. Each in-process sidewall spacer 57′ may be divided into a plurality of sidewall spacers 57 located on a sidewall of a respective layer stack (58, 56, 54). In one embodiment, each in-process bottom liner 52′ may be divided into a plurality of bottom liners 52 contacting a bottom surface of a respective one of the phase change material portions 54 and contacting a bottom surface of a respective one of the sidewall spacers 57. The second patterned etch mask layer 79 may be subsequently removed, for example, by ashing or dissolution in a solvent.

Generally, a plate stack (58′, 56′, 54′) may be patterned into at least one row of layer stacks (58, 56, 54) arranged along a first horizontal direction hd1 or along a second horizontal direction hd2. In one embodiment, each plate stack (58′, 56′, 54′) may be divided into an M x N array of layer stacks (58, 56, 54). In one embodiment, the second exemplary structure may comprise a P×Q array of plate stacks (58′, 56′, 54′) after the processing step of FIG. 12, and each plate stack (58′, 56′, 54′) may be divided into an M×N array of layer stacks (58, 56, 54). In this embodiment, a PM×QN array of layer stacks (58, 56, 54) may be formed by the anisotropic etch process. P and Q may be independent integers greater than 1, and may be independently in a range from 2 to 2¹⁶.

In summary, the in-process sidewall spacers 57′, the in-process top electrodes 56′, and the in-process phase change material portions 54′ may be patterned into sidewall spacers 57, top electrodes 56, and phase change material portions 54, respectively. Vertical stacks comprising a respective bottom liner 52, a respective phase change material portion 54, and a respective top electrode 56 and sidewall spacers 57 are formed.

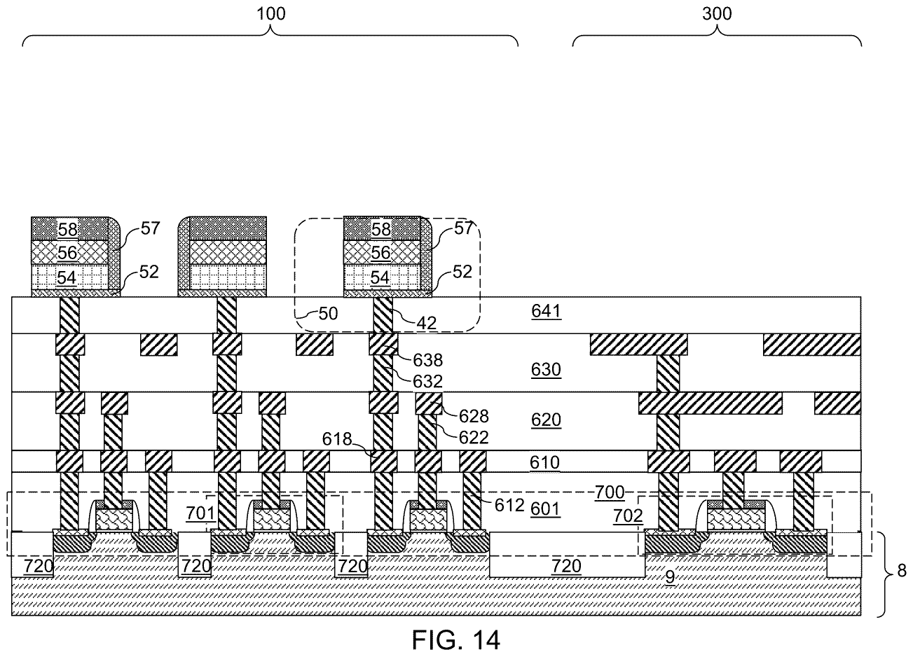

Referring to FIG. 14, the second exemplary structure is illustrated after formation of stacks of a hardmask plate 58, a top electrode 56, and a phase change material portion 54. Each contiguous combination of a bottom electrode 42, a bottom liner 52, a phase change material portion 54, a top electrode 56, a hardmask plate 58, and a sidewall spacer 57 constitutes a phase change memory cell 50. A two-dimensional array of phase change memory cells 50 may be formed in the memory array region 100. Each phase change memory cell 50 comprises a bottom electrode 42 located within a dielectric material layer (such as a lower fourth interconnect-level dielectric material layer 641); a stack comprising a bottom liner 52, a phase change material portion 54, and a top electrode 56 and located on the bottom electrode 42; and a sidewall spacer 57 contacting sidewalls of the top electrode 56 and the phase change material portion 54 and contacting a peripheral segment of a top surface of the bottom liner 52. For each phase change memory cell 50, at least one first sidewall of the bottom liner 52 is vertically coincident with a respective outer sidewall of the sidewall spacer 57, and at least one second sidewall of the bottom liner 52 is vertically coincident with a respective sidewall of a respective overlying phase change material portion 54.

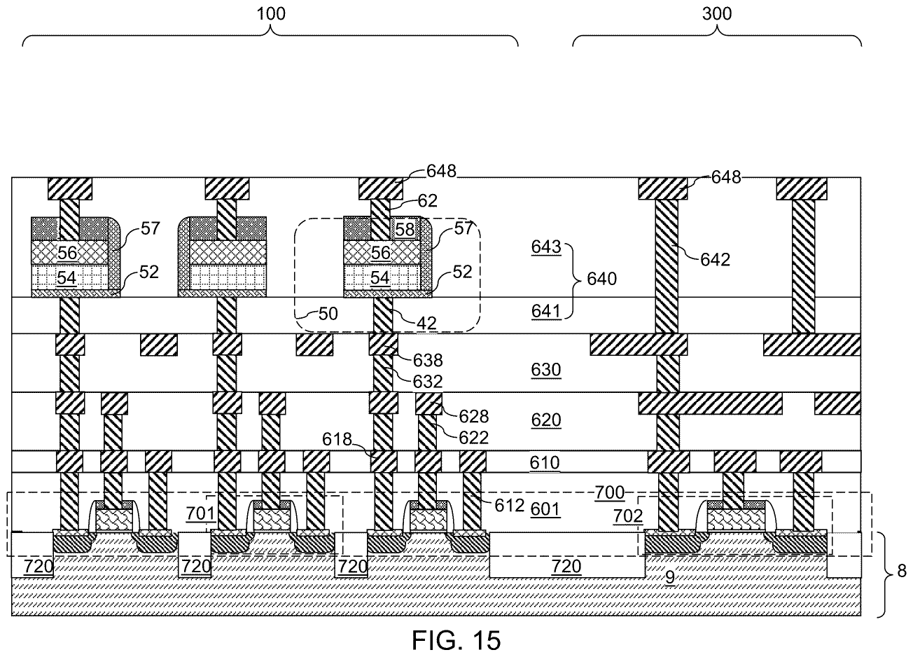

Referring to FIG. 15, an encapsulation dielectric layer 643 and additional metal interconnect structures (62, 642, 648) may be formed over the phase change memory cells 50. The encapsulation dielectric layer 643 comprises at least one interlayer dielectric material such as silicon oxide, silicon nitride, and/or silicon carbide nitride. The additional metal interconnect structures (62, 642, 648) may comprise top-contact via structures 62 contacting a top surface of a respective one of the top electrodes 56, peripheral via structures 642 that are formed on a respective one of the lower-level metal interconnect structures (612, 618, 622, 628, 632, 638) (such as a respective one of the third metal line structures 638), and fourth metal line structures 648 that are formed on the top-contact via structures 62 and the peripheral via structures 642. Top surfaces of the fourth metal line structures 648 may be coplanar with the horizontal top surface of the encapsulation dielectric layer 643.

The encapsulation dielectric layer 643 constitutes an upper fourth interconnect-level dielectric material layer. The combination of the lower fourth interconnect-level dielectric material layer 641 and the encapsulation dielectric layer 643 constitutes a fourth interconnect-level dielectric material layer 640. Additional dielectric material layers (not shown) and additional metal interconnect structures may be formed to provide electrical connections between the top electrodes 56 of the phase change memory cells 50 and the various semiconductor devices 700 that underlie the dielectric material layers (601, 610, 620, 630, 640).

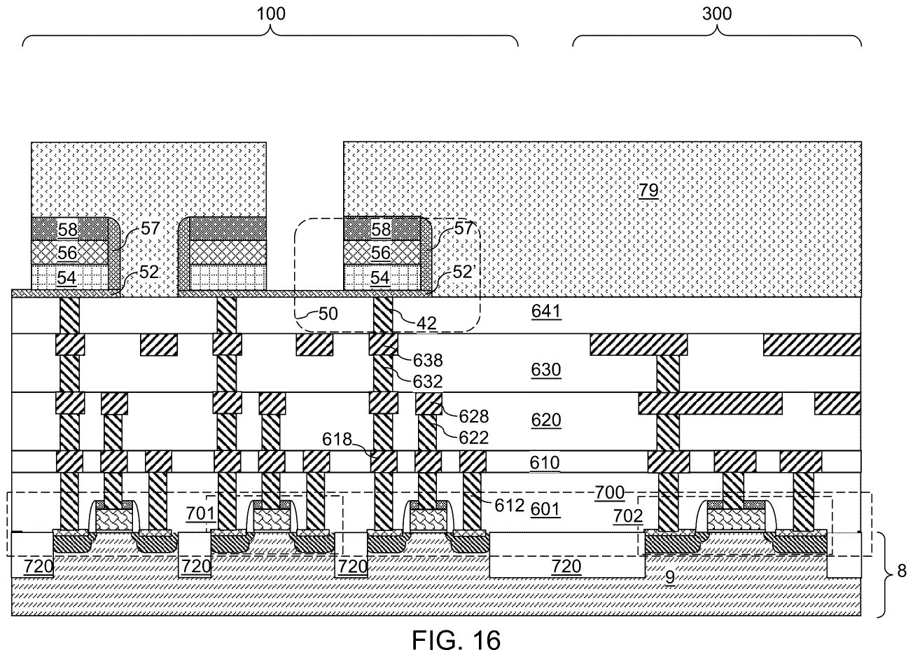

Referring to FIG. 16, a third exemplary structure according to a third embodiment of the present disclosure is illustrated. The third exemplary structure illustrated in FIG. 16 may be derived from the second exemplary structure described with reference to FIG. 13B by performing the processing steps described with reference to FIG. 13C with a modification. Specifically, the anisotropic etch process described with reference to FIG. 13C is modified not to etch the material of the bottom liner layer 52L, i.e., the material of the in-process bottom liners 52′. In the third embodiment, the spacer material layer 57L may be referred to as an inner spacer material layer 57L.

In the third embodiment, the anisotropic etch process etches unmasked portions of the in-process hardmask plates 58′, the in-process top electrodes 56′, the in-process phase change material portions 54′, and the in-process sidewall spacers 57′ without etching the in-process bottom liners 52′. In this embodiment, the anisotropic etch process may comprise a first anisotropic etch step that etches the material of the in-process hardmask plates 58 without completely etching the in-process sidewall spacers 57′, a second anisotropic etch step that etches the material of the in-process top electrodes 56′ selectively to the material of the in-process sidewall spacers 57′, and a combination of a third anisotropic etch process and a fourth anisotropic etch process that etches the materials of the in-process phase change material portions 54′ and the in-process sidewall spacers 57′ selectively to the material of the in-process bottom liners 52′. In one embodiment, the third anisotropic etch process etches the material of the in-process phase change material portions 54′ selectively to the material of the in-process bottom liners 52′ and the fourth anisotropic etch process etches the material of the in-process sidewall spacers 57′ selectively to the material of the in-process bottom liners 52′. In another embodiment, the third anisotropic etch process etches the material of the in-process sidewall spacers 57′ selectively to the material of the in-process bottom liners 52′ and the fourth anisotropic etch process etches the material of the in-process phase change material portions 54′ selectively to the material of the in-process bottom liners 52′.

In the third embodiment, the anisotropic etch process etches the material of the remaining portions of the in-process phase change material portions 54′ (which are phase change material portions 54) selectively to the material of the in-process bottom liners 52′ and etches the material of the in-process sidewall spacers 57′ selectively to the material of the in-process bottom liners 52′. By not patterning the in-process bottom liners 52′ while the sidewalls of the patterned portions of the phase change material layer 54L are physically exposed, chemical and structural damages to the material of the patterned portions of the phase change material layer 54L are avoided. Lack of damage to the material of the patterned portions of the phase change material layer 54L allows phase change memory cells to be subsequently formed to provide consist and reliable switching characteristics between a low resistance state and a high resistance state.

The anisotropic etch process etches unmasked regions of the combination of the plate stacks (58′, 56′, 54′) and the in-process sidewall spacers 57′ (which are remaining portion of the spacer material layer 57L after the processing steps of FIG. 12) without etching the unmasked portions of the in-process bottom liners 52′ (which are the patterned remaining portions of the bottom liner layer 52L after the processing steps of FIG. 12). Each contiguous set of patterned portions of a plate stack (58′, 56′, 54′) comprises a layer stack (58, 56, 54) including a respective hardmask plate 58, a respective top electrode 56, and a respective phase change material portion 54.

Thus, the anisotropic etch process further patterns the remaining patterned portions of the hardmask material layer 58L, the remaining patterned portions of the top electrode material layer 56L, the remaining patterned portions of the phase change material layer 54L, and the remaining portions of the spacer material layer 57L that remain after the processing steps of FIG. 12 (i.e., the first bottom-liner etch process). Remaining portions of the hardmask material layer 58L after the second anisotropic etch process comprises hardmask plates 58. Remaining portions of the top electrode material layer 56L after the second anisotropic etch process comprises top electrodes 56. Remaining portions of the phase change material layer 54L after the second anisotropic etch process comprises phase change material portions 54.

Generally, a plate stack (58′, 56′, 54′) may be patterned into at least one row of layer stacks (58, 56, 54) arranged along a first horizontal direction hd1 or along a second horizontal direction hd2. In one embodiment, each plate stack (58′, 56′, 54′) may be divided into an M x N array of layer stacks (58, 56, 54). In one embodiment, the second exemplary structure may comprise a P×Q array of plate stacks (58′, 56′, 54′) after the processing step of FIG. 12, and each plate stack (58′, 56′, 54′) may be divided into an M×N array of layer stacks (58, 56, 54). In this embodiment, a PM×QN array of layer stacks (58, 56, 54) may be formed by the anisotropic etch process. P and Q may be independent integers greater than 1, and may be independently in a range from 2 to 2¹⁶.

Vertical stacks comprising a respective bottom liner 52, a respective phase change material portion 54, and a respective top electrode 56 are formed. Further, inner sidewall spacers 57 are formed, which comprise patterned portions of the inner spacer material layer 57L. In summary, the in-process sidewall spacers 57′, the in-process top electrodes 56′, and the in-process phase change material portions 54′ may be patterned into inner sidewall spacers 57, top electrodes 56, and phase change material portions 54, respectively.

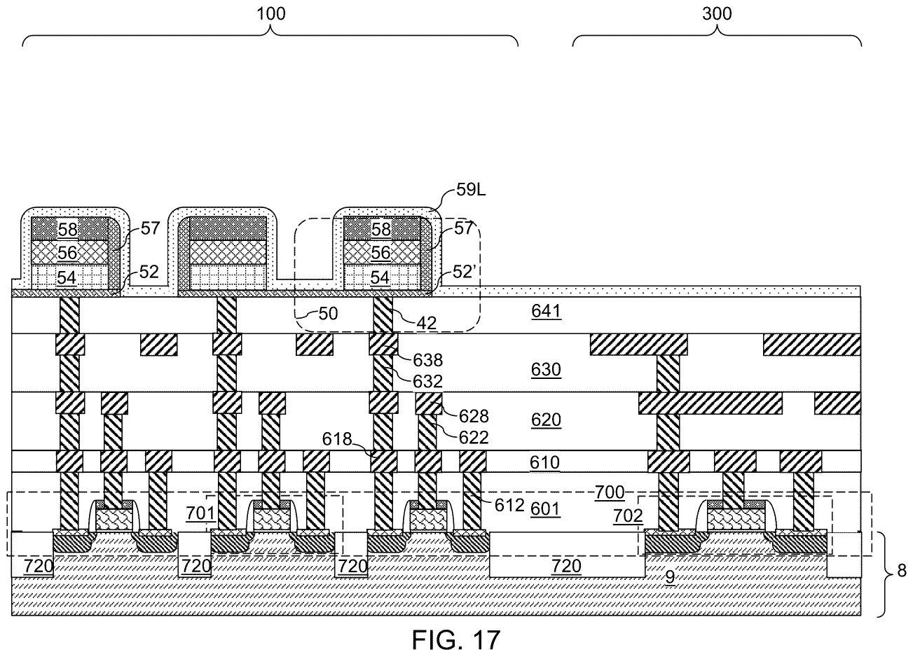

Referring to FIG. 17, an outer spacer material layer 59L may be formed around, and over, the vertical stacks (58, 56, 54) and the inner sidewall spacers 57, which are remaining portions of the combination of the plate stacks (58′, 56′, 54′) and the remaining portions of the spacer material layer 57L that remain after the anisotropic etch process. The outer spacer material layer 59L is formed by a conformal deposition of a dielectric material over the in-process bottom liners 52′, which are remaining portions of the bottom liner layer 52L after the anisotropic etch process described with reference to FIG. 16. The outer spacer material layer 59L may have an electrical conductivity less than 1.0×10⁻⁵ S/m. In one embodiment, the electrical conductivity of the outer spacer material layer 59L may be lower than the electrical conductivity of the material of the spacer material layer 57L (i.e., the material of the inner sidewall spacers 57). In one embodiment, the outer spacer material layer 59L may comprise silicon nitride, silicon oxide, silicon oxynitride, and/or a dielectric metal oxide. The outer spacer material layer 59L may be deposited by a conformal deposition process such as a chemical vapor deposition process. The thickness of the outer spacer material layer 59L may be in a range from 1 nm to 20 nm, such as from 2 nm to 5 nm, although lesser or greater thicknesses may also be used.

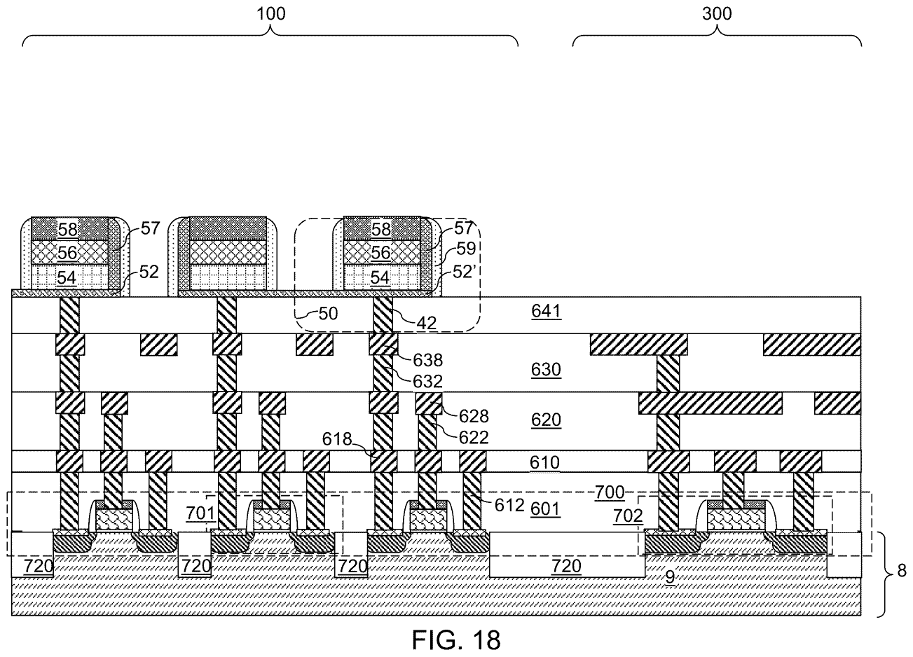

Referring to FIG. 18, a third anisotropic etch process may be performed to remove horizontally-extending portions of the outer spacer material layer 59L. The third anisotropic etch process is also referred to as an outer spacer etch process. The third anisotropic etch process anisotropically etches the material of the outer spacer material layer 59L, and removes horizontally-extending portions of the outer spacer material layer 59L. The etch chemistry of the third anisotropic etch process may be, or may not be, selective to the material of the in-process bottom liners 52′. Each remaining vertically-extending portion of the outer spacer material layer 59L constitutes an outer sidewall spacer 59 that laterally surrounds a respective plate stack (58, 56, 54) and a respective inner sidewall spacer 57. Each outer sidewall spacer 59 contacts a first subset of the sidewalls of a respective plate stack (58, 56, 54), and an outer sidewall of a respective inner sidewall spacer 57. Generally, an outer sidewall spacer 59 may be formed around each combination of a plate stack (58, 56, 54) and an inner sidewall spacer 57 by conformally depositing and anisotropically etching a layer of an outer sidewall spacer material.

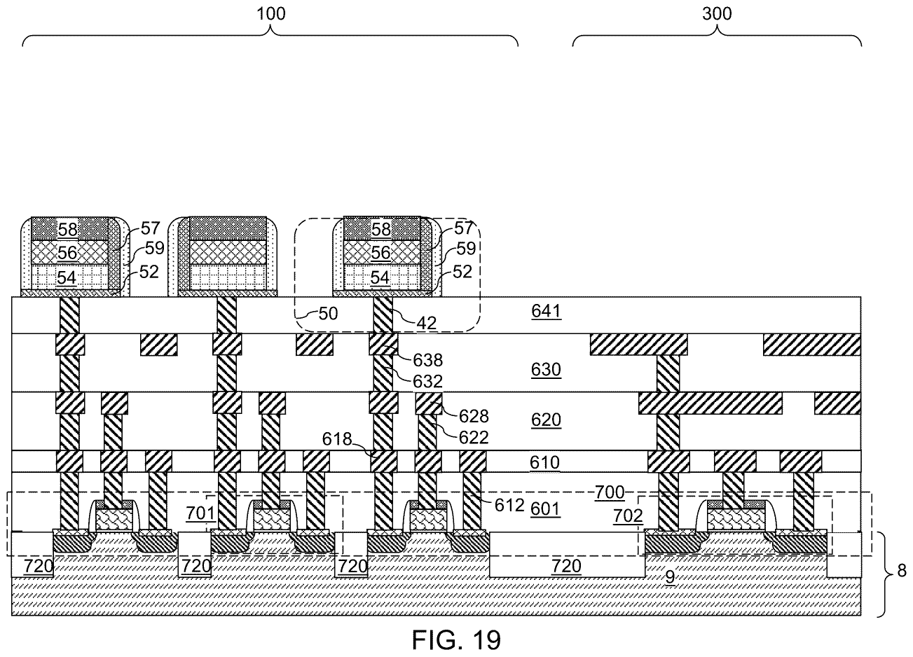

Referring to FIG. 19, a fourth anisotropic etch process may be performed to etch unmasked portions of the in-process bottom liners 52′. The fourth anisotropic etch process is also referred to as a second bottom-liner etch process. The fourth anisotropic etch process anisotropically etches unmasked portions of the material of the bottom liner layer 52L that are not covered by the combination of the plate stacks (58, 56, 54), the inner sidewall spacers 57 (which are vertically-extending remaining portions of the inner spacer material layer 57L), and the outer sidewall spacers 59 (which are vertically-extending remaining portions of the outer spacer material layer 59L). Each patterned remaining portions of the bottom liner layer 52L constitutes a bottom liner 52. Thus, the fourth anisotropic etch process patterns the in-process bottom liners 52′ into bottom liners 52. Each bottom liner 52 comprises a respective set of at least one first sidewall that is vertically coincident with a respective outer sidewall of a respective overlying inner sidewall spacer 57 (which is a remaining portion of the inner spacer material layer 57L), and a respective set of at least one second sidewall that is vertically coincident with a respective outer sidewall of a respective overlying outer sidewall spacer 59.

Each contiguous combination of a bottom electrode 42, a bottom liner 52, a phase change material portion 54, a top electrode 56, a hardmask plate 58, an inner sidewall spacer 57, and an outer sidewall spacer 59 constitutes a phase change memory cell 50. A two-dimensional array of phase change memory cells 50 may be formed in the memory array region 100. For each phase change memory cell 50, a peripheral segment of the top surface of the bottom liner 52 has a frame shape having an inner periphery and an outer periphery that is laterally offset outward relative to the inner periphery by a uniform lateral offset distance (which equals a lateral thickness of an outer sidewall spacer 57). In one embodiment, a frame-shaped bottom surface of the outer sidewall spacer 59 contacts an entirety of the peripheral segment of the top surface of the bottom liner 52.

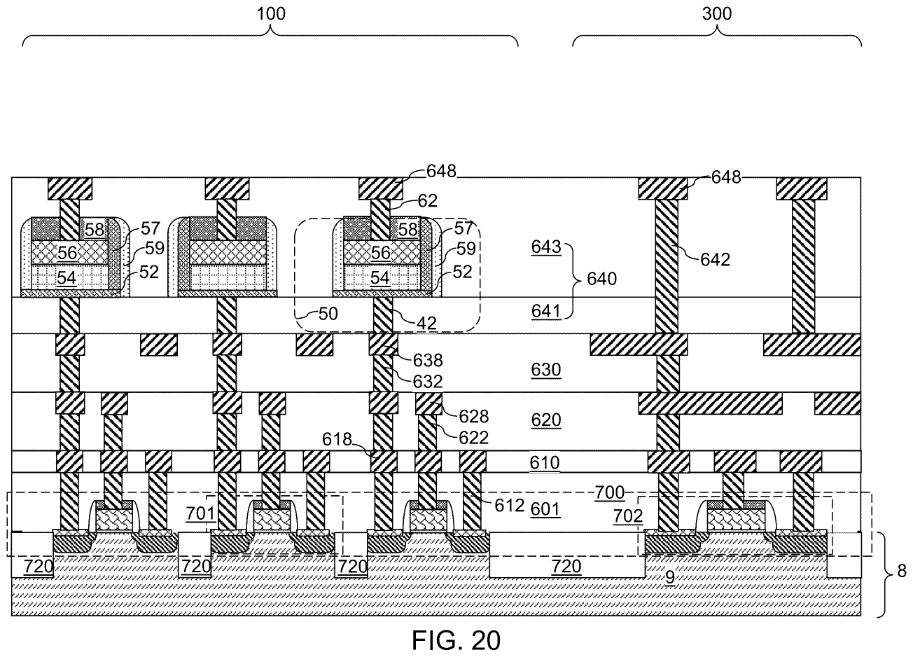

Referring to FIG. 20, an encapsulation dielectric layer 643 and additional metal interconnect structures (62, 642, 648) may be formed over the phase change memory cells 50. The encapsulation dielectric layer 643 comprises at least one interlayer dielectric material such as silicon oxide, silicon nitride, and/or silicon carbide nitride. The additional metal interconnect structures (62, 642, 648) may comprise top-contact via structures 62 contacting a top surface of a respective one of the top electrodes 56, peripheral via structures 642 that are formed on a respective one of the lower-level metal interconnect structures (612, 618, 622, 628, 632, 638) (such as a respective one of the third metal line structures 638), and fourth metal line structures 648 that are formed on the top-contact via structures 62 and the peripheral via structures 642. Top surfaces of the fourth metal line structures 648 may be coplanar with the horizontal top surface of the encapsulation dielectric layer 643.

The encapsulation dielectric layer 643 constitutes an upper fourth interconnect-level dielectric material layer. The combination of the lower fourth interconnect-level dielectric material layer 641 and the encapsulation dielectric layer 643 constitutes a fourth interconnect-level dielectric material layer 640. Additional dielectric material layers (not shown) and additional metal interconnect structures may be formed to provide electrical connections between the top electrodes 56 of the phase change memory cells 50 and the various semiconductor devices 700 that underlie the dielectric material layers (601, 610, 620, 630, 640).

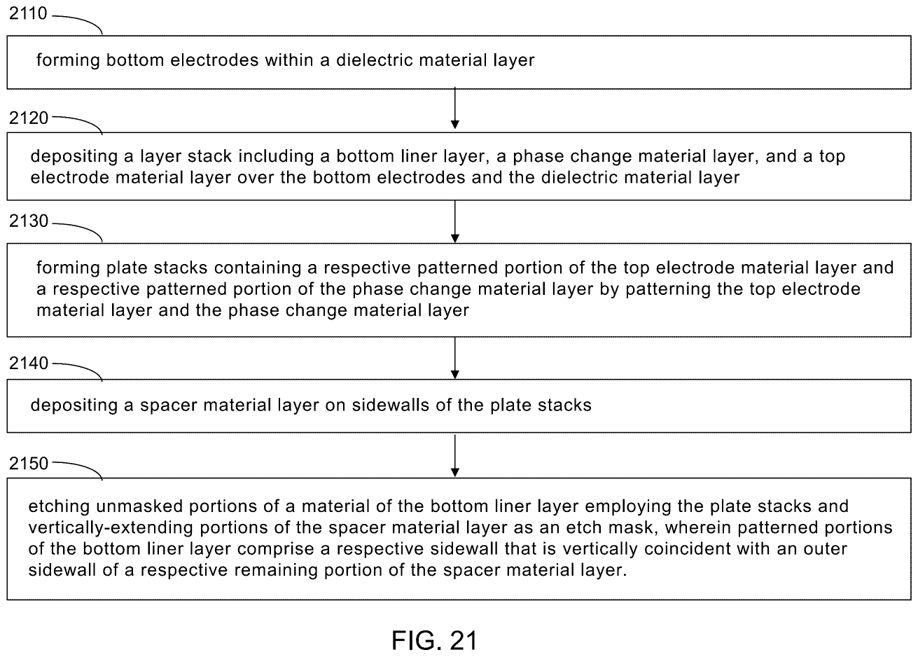

FIG. 21 is a first flowchart that illustrates general processing steps for manufacturing a device structure according to embodiments of the present disclosure.

Referring to step 2110 and FIGS. 1 and 2, bottom electrodes 42 may be formed within a dielectric material layer (such as a lower fourth interconnect-level dielectric material layer 641).

Referring to step 2120 and FIG. 3, a layer stack including a bottom liner layer 52L, a phase change material layer 54L, and a top electrode material layer 56L may be formed over the bottom electrodes 42 and the dielectric material layer (such as a lower fourth interconnect-level dielectric material layer 641).

Referring to step 2130 and FIGS. 4 and 9, plate stacks {(58, 56, 54) or (58′, 56′, 54′)} containing a respective patterned portion of the top electrode material layer 56L and a respective patterned portion of the phase change material layer 54L may be formed by patterning the top electrode material layer 56L and the phase change material layer 54L.

Referring to step 2140 and FIGS. 5 and 10, a spacer material layer 57L may be deposited on sidewalls of the plate stacks (58, 56, 54).

Referring to step 2150 and FIGS. 6-8 and 11-20, unmasked portions of a material of the bottom liner layer 52L may be etched using the plate stacks {(58, 56, 54) or (58′, 56′, 54′)} and vertically-extending portions of the spacer material layer 57L as an etch mask. Patterned portions of the bottom liner layer 52L comprise a respective sidewall that is vertically coincident with an outer sidewall of a respective remaining portion of the spacer material layer 57L.

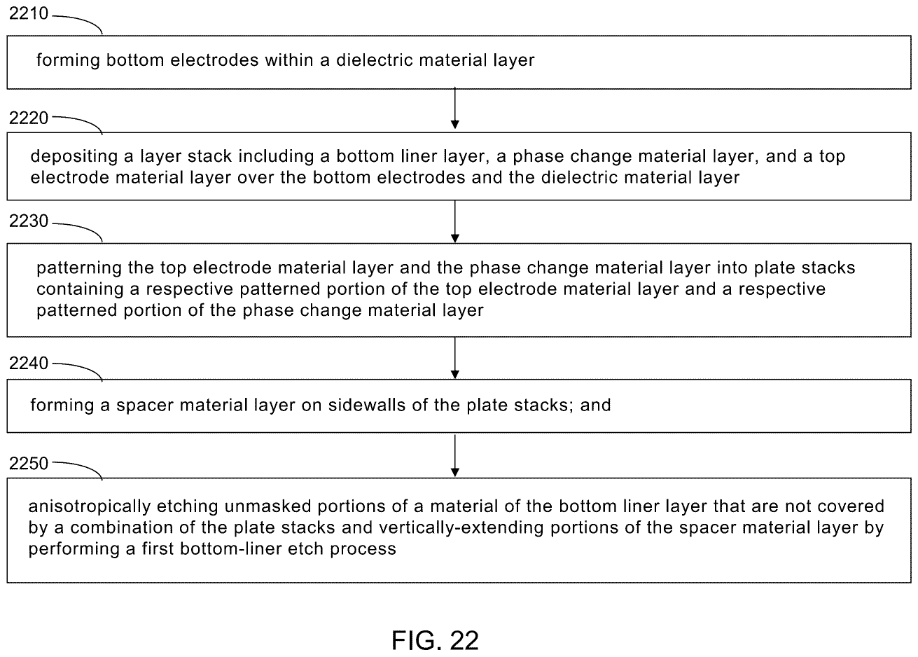

FIG. 22 is a second flowchart that illustrates general processing steps for manufacturing a device structure according to embodiments of the present disclosure.

Referring to step 2210 and FIGS. 1 and 2, bottom electrodes 42 are formed within a dielectric material layer (such as a lower fourth interconnect-level dielectric material layer 641).

Referring to step 2220 and FIG. 3, a layer stack including a bottom liner layer 52L, a phase change material layer 54L, and a top electrode material layer 56L may be deposited over the bottom electrodes 42 and the dielectric material layer (such as a lower fourth interconnect-level dielectric material layer 641).

Referring to step 2230 and FIGS. 4 and 9, the top electrode material layer 56L and the phase change material layer 54L may be patterned into plate stacks {(58, 56, 54) or (58′, 56′, 54′)} containing a respective patterned portion of the top electrode material layer 56L and a respective patterned portion of the phase change material layer 54L.

Referring to step 2240 and FIGS. 5 and 10, a spacer material layer 57L may be formed on sidewalls of the plate stacks {(58, 56, 54) or (58′, 56′, 54′)}.

Referring to step 2250 and FIGS. 6-8 and 11-20, unmasked portions of a material of the bottom liner layer 52L that are not covered by a combination of the plate stacks (58, 56, 54) and vertically-extending portions of the spacer material layer 57L may be anisotropically etched by performing a first bottom-liner etch process.

Referring to all drawings and according to various embodiments of the present disclosure, a device structure is provided, which comprises: a bottom electrode 42 located within a dielectric material layer (such as a lower fourth interconnect-level dielectric material layer 641); a stack comprising a bottom liner 52, a phase change material portion 54, and a top electrode 56 and located on the bottom electrode 42; and a sidewall spacer 57 contacting sidewalls of the top electrode 56 and the phase change material portion 54 and contacting a peripheral segment of a top surface of the bottom liner 52.

In one embodiment, the peripheral segment of the top surface of the bottom liner 52 has a frame shape having an inner periphery and an outer periphery that is laterally offset outward relative to the inner periphery by a uniform lateral offset distance; and a frame-shaped bottom surface of the sidewall spacer 57 contacts an entirety of the peripheral segment of the top surface of the bottom liner 52. In one embodiment, a first sidewall of the bottom liner 52 is vertically coincident with an outer sidewall of the sidewall spacer 57. In one embodiment, a second sidewall of the bottom liner 52 is laterally offset relative to a most proximal outer sidewall of the sidewall spacer 57.

In one embodiment, the bottom liner layer 52L comprises a conductive material having a first electrical conductivity grater than 1.0×10⁵ S/m; and the spacer material layer 57L comprises a material having a second electrical conductivity in a range from 1.0×10⁻¹⁵ S/m to 1.0×10³ S/m.

In previously known phase change memory devices, the sidewalls of phase change material portions were susceptible to damage or segregation during certain fabrication steps, particularly during the liner cutting process. This damage could occur when the sidewalls were exposed to halogen-based gases used in etching metallic materials, potentially leading to segregation or structural changes in the phase change material. Such damage may impact the ability to control phase changing between crystalline and amorphous states in the phase change material, affecting device functionality and performance characteristics.

In the present disclosure, the sidewalls of the phase change material portions 54 are protected by a sidewall spacer 57, and in some embodiments, further protected by an outer sidewall spacer 59 during the etch process(es) that etch(es) the metallic material of the bottom liner layer 52L. Embodiments of the present disclosure prevent damage or segregation of the phase change material sidewall during the patterning process that forms the bottom liners 52. Sidewall spacers 57 and optionally outer sidewall spacers 59 are formed before patterning the bottom liner layer 52L, and function as protective barrier structures for preventing damage to phase change material portions 54. Use of the sidewall spacers 57 and the optional outer sidewall spacers 59 increases the integrity and the functionality of the phase change memory cells 50, and increases the reliability of the transition of the phase change material portions 54 between a crystalline state and an amorphous state. Thus, the enhanced protection of the sidewalls of the phase change material portions 54 increases the reliability and performance of the phase change memory cells 50, allowing for more consistent and controllable switching characteristics between low and high resistance states.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming bottom electrodes within a dielectric material layer;
depositing a layer stack including a bottom liner layer, a phase change material layer, and a top electrode material layer over the bottom electrodes and the dielectric material layer;
forming plate stacks containing a respective patterned portion of the top electrode material layer and a respective patterned portion of the phase change material layer by patterning the top electrode material layer and the phase change material layer;
depositing a spacer material layer on sidewalls of the plate stacks; and
etching unmasked portions of a material of the bottom liner layer using the plate stacks and vertically-extending portions of the spacer material layer as an etch mask, wherein patterned portions of the bottom liner layer comprise a respective sidewall that is vertically coincident with an outer sidewall of a respective remaining portion of the spacer material layer.

2. The method of claim 1, wherein the top electrode material layer and the phase change material layer are patterned into the plate stacks by performing an anisotropic etch process that etches materials of the top electrode material layer and the phase change material layer selectively to the material of the bottom liner layer.

3. The method of claim 2, wherein the spacer material layer is deposited directly on a top surface of a remaining portion of the bottom liner layer after patterning the top electrode material layer and the phase change material layer into the plate stacks.

4. The method of claim 1, wherein the bottom liner layer covers, and contacts, an entire top surface of the dielectric material layer after patterning the top electrode material layer and the phase change material layer into the plate stacks.

5. The method of claim 1, wherein all sidewalls of the plate stacks are contacted by the spacer material layer upon deposition of the spacer material layer.

6. The method of claim 1, wherein:
the respective patterned portion of the top electrode material layer comprises a respective top electrode;
the respective patterned portion of the phase change material layer comprises a respective phase change material portion; and
the spacer material layer is formed on all sidewalls of the respective top electrode and the respective phase change material portion.

7. The method of claim 1, wherein:
the respective patterned portion of the top electrode material layer comprises a respective in-process top electrode;
the respective patterned portion of the phase change material layer comprises a respective in-process phase change material portion; and
the method further comprises patterning the in-process top electrodes, the in-process phase change material portions, the remaining portion of the spacer material layer, and the patterned portions of the bottom liner layer, whereby vertical stacks comprising a respective bottom liner, a respective phase change material portion, and a respective top electrode and sidewall spacers are formed.

8. The method of claim 7, further comprising:
forming a patterned photoresist layer over the in-process top electrodes and the in-process phase change material portions; and
anisotropically etching unmasked regions of a combination of the plate stacks, the remaining portion of the spacer material layer, and the patterned portions of the bottom liner layer that are not covered by the patterned photoresist layer, wherein remaining portions of the patterned portions of the bottom liner layer comprise the bottom liners.

9. The method of claim 7, further comprising:
forming a patterned photoresist layer over the in-process top electrodes and the in-process phase change material portions; and
anisotropically etching unmasked portions of a combination of the plate stacks and the remaining portion of the spacer material layer selectively to the material of the bottom liner layer by performing an anisotropic etch process.

10. The method of claim 9, further comprising:
removing the patterned photoresist layer;
conformally depositing an outer spacer material layer around, and over, remaining portions of the combination of the plate stacks and the remaining portion of the spacer material layer that remain after the anisotropic etch process and over a remaining portion of the bottom liner layer after the anisotropic etch process;
forming outer sidewall spacers by anisotropically etching the outer spacer material layer; and
etching unmasked portions of the remaining portion of the bottom liner layer using a combination of the remaining portions of the plate stacks, the sidewall spacers, and the outer sidewall spacers as an etch mask.

11. A method of forming a device structure, comprising:
forming bottom electrodes within a dielectric material layer;
depositing a layer stack including a bottom liner layer, a phase change material layer, and a top electrode material layer over the bottom electrodes and the dielectric material layer;
patterning the top electrode material layer and the phase change material layer into plate stacks containing a respective patterned portion of the top electrode material layer and a respective patterned portion of the phase change material layer;
forming a spacer material layer on sidewalls of the plate stacks; and
anisotropically etching unmasked portions of a material of the bottom liner layer that are exposed outside areas of a combination of the plate stacks and vertically-extending portions of the spacer material layer by performing a first bottom-liner etch process.

12. The method of claim 11, wherein:
the respective patterned portion of the top electrode material layer comprises a respective top electrode;
the respective patterned portion of the phase change material layer comprises a respective phase change material portion; and
the vertically-extending portions of the spacer material layer contact each sidewall of a respective one of the top electrodes and each sidewall of a respective one of the phase change material portions.

13. The method of claim 11, wherein:
the respective patterned portion of the top electrode material layer comprises a respective in-process top electrode;
the respective patterned portion of the phase change material layer comprises a respective in-process phase change material portion;
remaining portions of the spacer material layer after the first bottom-liner etch process comprise in-process sidewall spacers, wherein each of the in-process sidewall spacers laterally surrounds a respective one of the in-process top electrodes and a respective one of the in-process phase change material portions; and
the method further comprises patterning the in-process sidewall spacers, the in-process top electrodes, and the in-process phase change material portions into sidewall spacers, top electrodes, and phase change material portions, respectively.

14. The method of claim 11, further comprising further patterning the patterned portions of the top electrode material layer and the patterned portions of the phase change material layer after the first bottom-liner etch process, wherein:
remaining portions of the bottom liner layer after the second anisotropic etch process comprise bottom liners;
remaining portions of the spacer material layer after the second anisotropic etch process comprise sidewall spacers; and
each of the bottom liners is formed with a first sidewall that is vertically coincident with an outer sidewall of a respective overlying one of the sidewall spacers.

15. The method of claim 11, further comprising performing a spacer etch process that anisotropically etches a material of the spacer material layer selectively to the material of the bottom liner layer before performing the first bottom-liner etch process, wherein the spacer etch process is an anisotropic etch process that removes horizontally-extending portions of the spacer material layer.

16. A device structure comprising:
a bottom electrode located within a dielectric material layer;
a stack comprising a bottom liner, a phase change material portion, and a top electrode and located on the bottom electrode; and
a sidewall spacer contacting sidewalls of the top electrode and the phase change material portion and contacting a peripheral segment of a top surface of the bottom liner.

17. The device structure of claim 16, wherein:
the peripheral segment of the top surface of the bottom liner has a frame shape having an inner periphery and an outer periphery that is laterally offset outward relative to the inner periphery by a uniform lateral offset distance; and
a frame-shaped bottom surface of the sidewall spacer contacts an entirety of the peripheral segment of the top surface of the bottom liner.

18. The device structure of claim 16, wherein a first sidewall of the bottom liner is vertically coincident with an outer sidewall of the sidewall spacer.

19. The device structure of claim 16, wherein a second sidewall of the bottom liner is laterally offset relative to a most proximal outer sidewall of the sidewall spacer.

20. The device structure of claim 16, wherein:
the bottom liner layer comprises a conductive material having a first electrical conductivity greater than 1.0×10⁵ S/m; and
the spacer material layer comprises a material having a second electrical conductivity in a range from 1.0×10⁻¹⁵ S/m to 1.0×10³ S/m.
